(19) United States
(12) Patent Application Publication
(10) Pub. No.: US 2023/0155563 A1
(43) Pub. Date: May 18, 2023

(54) ATOMIC LAYER DEPOSITION IN ACOUSTIC WAVE RESONATORS

(71) Applicant: MACOM Technology Solutions Holdings, Inc., Lowell, MA (US)

(72) Inventors: Rathnait Long, North Andover, MA (US); Douglas Carlson, Hopkinton, MA (US)

(21) Appl. No.: 17/527,764

(22) Filed: Nov. 16, 2021

(51) Int. Cl. H03H 3/02; H03H 9/17; H03H 9/13

(52) U.S. Cl. CPC H03H 3/02; H03H 9/171; H03H 9/13

(57) ABSTRACT

Aspects of acoustic resonators and methods of manufacture of acoustic resonators are described, including acoustic resonators with thinner layers of piezoelectric material. In one example, a method of manufacturing an acoustic resonator includes providing a substrate, depositing a layer of piezoelectric material over the substrate by atomic layer deposition (ALD), and forming an electrode in contact with the layer of piezoelectric material. ALD is used to deposit highly uniform and conformal thin films of piezoelectric material and, in some cases, electrodes and encapsulation layers. The acoustic resonators described herein are better suited for the demands of new radio frequency (RF) filters, duplexers, transformers, and other components in front-end radio electronics and other applications.

### BACKGROUND

The piezoelectric effect is exhibited by certain materials, and it is related to the electromechanical interaction between the mechanical and electrical states in the materials. Materials that exhibit the piezoelectric effect also exhibit the reverse piezoelectric effect. For example, lead zirconate titanate crystals generate piezoelectricity (i.e., generate an electric field potential) when mechanical forces are applied to deform the shape of the crystals. Lead zirconate titanate crystals will also deform or change in shape when an external electric field is applied to the crystals.

Piezoelectric materials can be categorized as either crystalline, ceramic, or polymeric materials. Lead zirconate titanate, barium titanate, and lead titanate are examples of piezoelectric ceramics materials. Certain semiconducting piezoelectric materials are compatible with semiconductor devices and integrated circuits. Gallium nitride and zinc oxide, among others, are examples of piezoelectric materials that are compatible with semiconductor devices and integrated circuits.

The electromechanical coupling coefficient of a piezoelectric material is a metric of the conversion efficiency between the electric and mechanical energy in the piezoelectric material. The electromechanical coupling coefficient can include parameters, such as the surfaces upon which electric potential is applied or formed and the direction along which mechanical energy is applied or developed in the material.

### SUMMARY

Various examples of the use of atomic layer deposition in the manufacture of semiconductor devices, and particularly acoustic wave resonators, are described, along with a number of new acoustic wave resonator devices incorporating one or more layers of material deposited using atomic layer deposition. In one example, a method of manufacturing an acoustic resonator includes providing a substrate, depositing a layer of piezoelectric material over the substrate by atomic layer deposition, and forming an electrode in contact with the layer of piezoelectric material.

In certain aspects of the embodiments, the electrode is a first electrode, and the method also includes forming a second electrode in contact with the piezoelectric material. The first electrode and the second electrode are formed by sputtering metal in one example. In another example, the first electrode is formed by atomic layer deposition of metal, and the second electrode is formed by sputtering metal. In still another example, the first electrode and the second electrode are both formed by atomic layer deposition of metal.

In other aspects, the first electrode and the second electrode are both formed at over the layer of piezoelectric material in a stack of material layers of the acoustic resonator. In another case, the first electrode is formed under the layer of piezoelectric material and the second electrode is formed over the layer of piezoelectric material in the stack of material layers of the acoustic resonator.

In other aspects, the method also includes forming an acoustic reflector over the substrate, between the substrate and the layer of piezoelectric material. The reflector includes a plurality of layers of material. The layers include alternating layers of material having varying refractive indexes. In one case, the method also includes forming a supporting layer over the substrate, between the substrate and the layer of piezoelectric material. The method can also include forming an air cavity in the substrate in a region below the piezoelectric material. The cavity includes a plurality of supporting pillars in one example.

In still other aspects, the method also includes, after depositing the layer of piezoelectric material by atomic layer deposition, trimming the layer of piezoelectric material. The method can also include forming an encapsulation layer over the electrode by atomic layer deposition. The piezoelectric material comprises aluminum nitride in one case, although other types of piezoelectric material can be relied upon.

An acoustic resonator is described in another example. The acoustic resonator includes a substrate, a layer of piezoelectric material deposited over the substrate by atomic layer deposition, and an electrode in contact with the layer of piezoelectric material. The layer of piezoelectric material includes a layer of aluminum nitride that is equal to or less than 100 nm in thickness in one example. The acoustic resonator also includes a second electrode in contact with the piezoelectric material in some cases. At least one of the electrode, the second electrode, or both electrodes are formed by atomic layer deposition of metal in one example. The acoustic resonator can include an acoustic reflector over the substrate, between the substrate and the layer of piezoelectric material. The acoustic reflector can also include a supporting layer over the substrate, between the substrate and the layer of piezoelectric material, among other layers.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments.

FIG. 1 is a perspective view of an example bulk acoustic wave (BAW) resonator structure according to various embodiments described herein.

FIG. 2 is a perspective view of an example surface acoustic wave (SAW) resonator structure according to various embodiments described herein.

FIG. 3 is a cross-sectional view of an example solidly mounted bulk acoustic wave resonator structure according to various embodiments described herein.

FIG. 4 illustrates an example method of manufacture of the resonator structure shown in FIG. 3 according to various embodiments described herein.

FIG. 5 is a cross-sectional view of an example thin-film bulk acoustic resonator according to various embodiments described herein.

FIG. 6 illustrates an example method of manufacture of the resonator structure shown in FIG. 5 according to various embodiments described herein.

FIG. 7 illustrates an example method of manufacture of the SAW resonator shown in FIG. 2 according to various embodiments described herein.

FIG. 8 is a cross-sectional view of an example laterally-excited bulk acoustic wave resonator according to various embodiments described herein.

FIG. 9 is a cross-sectional view of another example laterally-excited bulk acoustic wave resonator according to various embodiments described herein.

FIG. 10 illustrates an example method of manufacture of the resonator structures shown in FIGS. 8 and 9 according to various embodiments described herein.

### DETAILED DESCRIPTION

An acoustic resonator can be formed as a structure including a layer of piezoelectric material with electrodes in contact with one or more surfaces of the piezoelectric material. Characteristics for high performance acoustic resonators include accurate frequency response, high quality factor, high piezoelectric coupling or bandwidth, and small temperature coefficient of frequency, among others.

Different types and structures of acoustic resonators have been relied upon as oscillators, radio frequency (RF) filters, duplexers, and transformers in electric circuits, as components in micro-electromechanical systems (MEMS), and for other purposes. Examples of acoustic resonators include bulk acoustic wave (BAW) resonators and surface acoustic wave (SAW) resonators. Examples of BAW resonators include solidly mounted resonators (SMR) and thin-film bulk acoustic resonators (FBAR) as described in further detail below. Like SAW resonators, the operation of BAW resonators is based on the piezoelectric effect exhibited by the layer of piezoelectric material.

A number of different materials can be relied upon as the piezoelectric material in a BAW or SAW. As one example, zinc oxide (ZnO) is a relatively common piezoelectric material for high-frequency FBAR structures. For some material processing techniques, the stoichiometry of two-compound materials, such as ZnO, can be easier to control as compared to three-compound materials, when manufactured by thin film methods. Relatively thin layers of piezoelectric materials have been formed by sol-gel wet-chemical techniques, sputtering, pulsed laser deposition, and other techniques.

Today, many cellular communications devices include duplexers, filters, and other RF circuits including one or more acoustic resonators. Cellular communications devices can include several such RF circuits, and acoustic resonators are being adopted and relied upon at a larger scale due to the increased complexity of radio frequency front end electronics. A common application of acoustic wave structures, for example, is in RF filters for cellular phones, global positioning systems, Wi-Fi® systems, and other systems that rely upon RF signals for data communications. Such RF filters are often formed using a network of acoustic resonators, in a ladder, lattice, or stacked topology, and are designed to prevent the transmission of certain frequencies or frequency bands and to permit the reception of certain frequencies or frequency bands. BAW filter technology is complementing SAW filter technology in areas where increased power handling capability is needed. Further, BAW structures can be manufactured on silicon substrates in high volumes and are widely supported by current semiconductor device fabrication methods.

Advancements are needed in acoustic resonator technology, however, as new applications will rely upon even higher frequencies in the RF spectrum for communications. Newer communications devices and standards demand components capable of suitable operation at higher frequencies, with less variation in characteristic response over wide ranges of temperature and power levels.

In the context outlined above, aspects of acoustic resonators and methods of manufacture of acoustic resonators are described, including acoustic resonators with thinner layers of piezoelectric material, thinner electrode layers, and other features that facilitate higher performance. In one example, a method of manufacturing an acoustic resonator includes providing a substrate, depositing a layer of piezoelectric material over the substrate by atomic layer deposition (ALD), and forming an electrode in contact with the layer of piezoelectric material. ALD is used to deposit highly uniform and conformal thin films of piezoelectric material and, in some cases, electrodes and encapsulation layers. The acoustic resonators described herein are better suited for the demands of new RF filters, duplexers, transformers, and other components in front-end radio electronics and other applications.

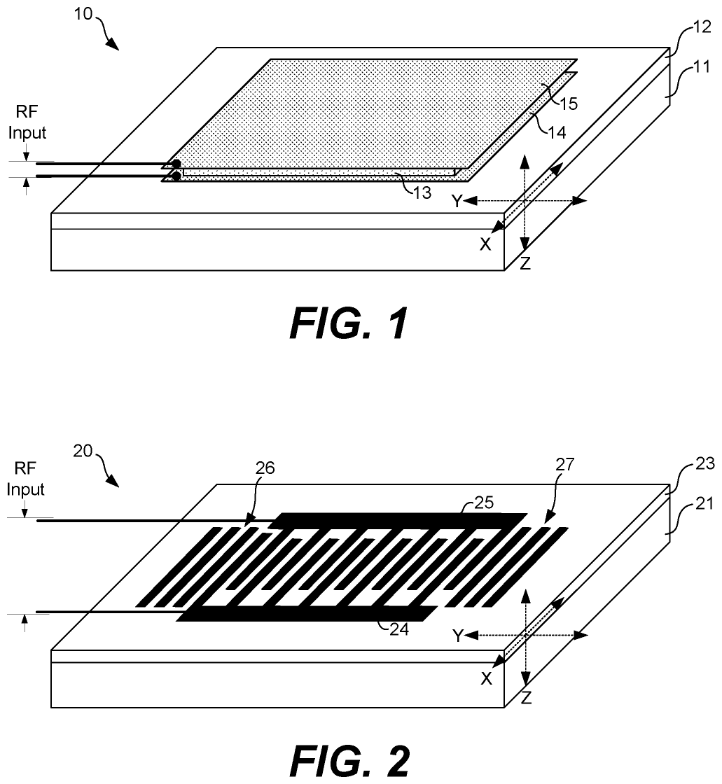

Turning to the drawings, FIG. 1 illustrates an example BAW resonator 10 according to various embodiments described herein. The illustration of the BAW resonator 10 is representative in FIG. 1. The positions, shapes, dimensions, and relative sizes of the layers and features of the BAW resonator 10 are not necessarily drawn to scale in FIG. 1. Example dimensions of the BAW resonator 10 are provided below, but the dimensions of the BAW resonator 10 are not specifically limited. The layers and other features shown in FIG. 1 are also not exhaustive, and the BAW resonator 10 can include other layers, features, and elements that are not separately illustrated. Additionally, the BAW resonator 10 can be formed as part of a larger integrated structure or circuit in combination with other devices and circuit elements. Such a larger integrated structure may include several resonators similar to the BAW resonator 10, among other integrated components.

The BAW resonator 10 includes a substrate 11, an intermediate region 12 over the substrate 11, a layer of piezoelectric material 13 over the substrate 11, a first electrode 14, and a second electrode 15. The first electrode 14 is in contact with a first surface (i.e., bottom surface) of the piezoelectric material 13 and positioned at least in part under the piezoelectric material 13, between the piezoelectric material 13 and the substrate 11. The second electrode 15 is in contact with a second surface (i.e., top surface) of the piezoelectric material 13 and positioned at least in part over the piezoelectric material 13. The BAW resonator 10 can also include additional layers described below but not illustrated in FIG. 1, such as a temperature compensation layer, an encapsulation layer, and other others.

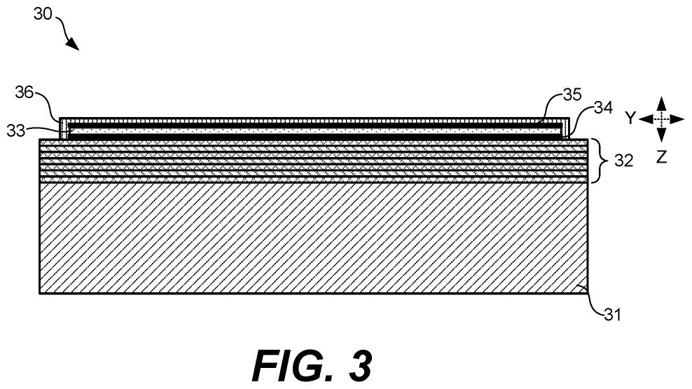

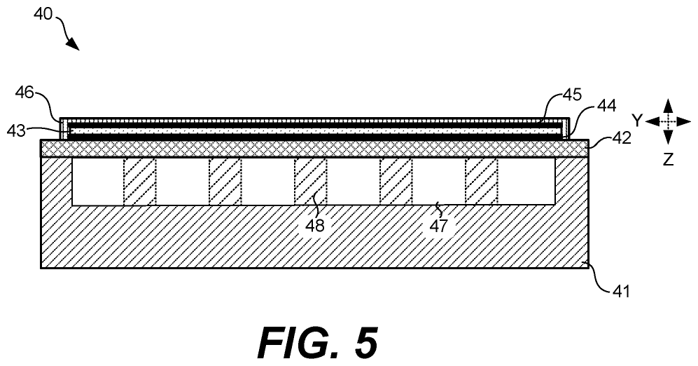

As depicted in FIG. 1, the BAW resonator 10 can be embodied as a solidly mounted resonator, a thin-film bulk acoustic resonator, or a related type of BAW resonator. An example solidly mounted resonator (SMR) is described in greater detail below with reference to FIG. 3, and an example thin-film bulk acoustic resonator (FBAR) is described in greater detail below with reference to FIG. 5. For an SMR, the intermediate region 12 can be embodied as an acoustic mirror or reflector, such as a Bragg reflector, as further described below. For an FBAR, the intermediate region 12 can be embodied as a supporting layer of silicon or other material, and the FBAR can also include a cavity or opening under the piezoelectric material 13 for acoustic wave isolation. In either case, due to the piezoelectric properties of the layer of piezoelectric material 13 and the structural arrangement of the BAW resonator 10, the BAW resonator 10 can generate a bulk acoustic or mechanical wave when an alternating electric potential input signal, such as an RF input, is applied across the electrodes 14 and 15. The bulk acoustic or mechanical wave can travel or translate in the “Z” direction down into the BAW resonator 10, as shown in FIG. 1, in the direction the thickness of the piezoelectric material 13 is measured.

The substrate 11 can be embodied as a silicon, silicon carbide, lithium niobate, sapphire, glass, ceramic, or another suitable type of substrate for the application. A silicon substrate may be preferred as being relatively low-cost, scalable for manufacturing, and compatible with manufacturing and processing steps, but other substrates can be relied upon. As noted above, the intermediate region 12 over the substrate 11 can be embodied as an acoustic mirror or a supporting layer, depending upon the type of resonator formed. Examples of the intermediate region 12 are described below with reference to FIGS. 3 and 5.

The electrodes 14 and 15 can be embodied as layers of highly conductive material, such as a metal or metal alloy, including copper, silver, gold, molybdenum, tungsten, titanium, platinum, or aluminum, alloys thereof, and other conductive layers. One factor in the material selection for the electrodes 14 and 15 is the desired thickness of the electrodes 14 and 15, which is also a factor in the response characteristics of the BAW resonator 10. Considerations in the selection of the conductive material for the electrodes 14 and 15 and the manner of forming the electrodes 14 and 15 are described below.

The layer of piezoelectric material 13 can be embodied as a layer of lead zirconate titanate (PZT), barium strontium titanate (BST), barium titanate (BaTiO3), aluminum scandium nitride (AlScN), aluminum nitride (AlN), ZnO, or another piezoelectric material. Despite the lower electromechanical coupling coefficient compared to ZnO, AlN has a wider band gap and is compatible with the silicon integrated circuit technology used in FBAR and other structures. AlN is also compatible with the ALD processing techniques as described herein. Thus, in one preferred embodiment, the layer of piezoelectric material 13 is a layer of AlN, although other piezoelectric materials can be relied upon. In some cases, the layer of piezoelectric material 13 can include one or more layers of piezoelectric material, including two or more different types of piezoelectric material (e.g., a stack of two or more of layers of AlN, PZT, BST, BaTiO3, and AlScN), each of which can be formed using ALD processing techniques according to the embodiments. The piezoelectric material 13 can also include a layer of AlN having a certain crystal orientation. In various embodiments, the layer of AlN can be formed to have a crystal structure c-axis orientation in the “X,” “Y,” or “Z” directions shown in FIG. 1. In one example, the layer of AlN can have a crystal structure c-axis orientation to excite a bulk acoustic or mechanical wave in the “Z” direction down into the BAW resonator 10.

The operating characteristics of the BAW resonator 10, including the frequency response, the accuracy of the frequency response, and the quality factor are determined in part by the thickness, conformity, and uniformity of the layer of piezoelectric material 13. Various sputtering techniques have been relied upon to form layers of piezoelectric material having a thickness of greater than about 300 nm or more. Current sputtering techniques cannot be reliably used to form layers of piezoelectric material that are thinner (e.g., such as 200 nm, 150 nm, or 100 nm in thickness or thinner) and also uniform and conformal. Thus, according to one aspect of the embodiments, the layer of piezoelectric material 13 can be embodied as a layer of AlN deposited by ALD. Forming the layer of AlN using ALD rather than sol-gel wet-chemical techniques, sputtering, pulsed laser deposition, or other techniques can result in thinner, more uniform, and more conformal layers of piezoelectric material.

As noted above, ALD is a process for depositing highly uniform and conformal thin films of material. The ALD process deposits thin films of material on a surface by the exposure of the surface to two chemical reactants. In one example, the process can be started with an initiation of the surface for the deposit of materials. The initiation can include annealing the surface, etching the surface, exposing the surface to one or more gases, or other steps to remove contaminants from the surface or otherwise prepare the surface for the deposit of materials.

After initiation, ALD processes typically proceed with the exposure of a surface to two or more precursor chemicals or reactants, in a repeating sequence. The precursors can be gaseous species introduced to an ALD chamber separately over time. The precursors react with the surface, respectively in time, in a self-limiting way (i.e., until the finite number of sites for the reaction are exhausted). Excess or remaining reactant of a precursor is removed before the next precursor or ALD cycle is applied or repeated. ALD processes are characterized by both dose times, which are the times that the surface is exposed to a respective precursor, and purge times, which are the times between doses during which the ALD chamber is evacuated for the next step. For a two reactant ALD process, a first reactant dose, first purge, second reactant dose, and second purge are steps in one ALD cycle.

A thin film is slowly deposited on the surface by the repeated exposure of the surface to the precursors, separately over time, with intermediate flushing steps in ALD processes. There is a maximum amount of material that can be deposited on the surface in a single ALD cycle, and it is determined by the precursor-surface interaction. The overall thickness of the thin film can be determined by the number of ALD cycles used, and the number of cycles can be tailored to grow uniform and conformal layers of material at a certain thickness with very high precision, even on complex surfaces. ALD processes are often characterized by the growth of material per ALD cycle, in nanometers or another suitable metric.

According to aspects of the embodiments, ALD can be used to form the layer of piezoelectric material 13 in the BAW resonator 10. The layer of piezoelectric material 13 can be formed as a thinner layer of piezoelectric material than in conventional BAW resonators, such as when sputtering is used. In one example, the layer of piezoelectric material 13 can be formed as an AlN layer of 100 nm in thickness or less by ALD. The layer of piezoelectric material 13 can be formed to be a thinner layer of AlN, however, such as a layer of less than 90 nm, 80 nm, 70 nm, 60 nm, 50 nm, 40 nm, 30 nm, or 20 nm in thickness in some cases using ALD. The layer of piezoelectric material 13 is not limited to a layer of AlN, as other thin films of piezoelectric materials can be formed using ALD.

The specific thickness of the layer of piezoelectric material 13 can be highly controlled or tailored in the BAW resonator 10, sometimes to within less than 10 nm of a target thickness, to within less than 5 nm of a target thickness, or even closer to a target thickness by using ALD. The layer of piezoelectric material 13 can be formed as thin as possible using a minimal number of ALD cycles in some embodiments. The use of ALD rather than sputtering to deposit the layer of piezoelectric material 13 offers a number of advantages. For example, the use of ALD reduces crystal damage in the layer of piezoelectric material 13, reduces dangling bonds, and reduces surface traps commonly attributed to sputter or plasma damage, resulting in better resonator performance.

The crystal orientation of the layer of piezoelectric material 13 can also be selected, in some cases, to tailor the operating characteristics of the BAW resonator 10. As one example, a thin film of ZnO having a crystal structure c-axis that is normal to (i.e., perpendicular to) a top surface of a supporting substrate excites longitudinal waves in the thin film. A thin film of ZnO having a crystal structure c-axis that is tilted to (i.e., not perpendicular to) a top surface of a supporting substrate can excite a shear or transversal wave in the thin film. It is also possible, depending on the crystal structure orientation, to excite a combination of both longitudinal and shear waves. Similar to a thin film of ZnO, the crystal orientation of a thin film of AlN also impacts the excitation of waves in the thin film and surrounding layers.

The crystal orientation of a thin film of piezoelectric material depends on various factors, including the materials processing techniques used to form the film or layer of material, the materials selected, the surface on which the film is grown or deposited, and the conditions in which the film is grown or deposited, such as the temperatures, pressures, gases, vacuum conditions, and other factors. The crystal orientation of the layer of piezoelectric material 13 in the BAW resonator 10 can be directed using one or more ALD processing steps according to aspects of the embodiments. For example, one or more initiation steps of the ALD process, and the ALD growth process itself, can be relied upon to direct the crystal structure c-axis orientation of the layer of piezoelectric material 13.

In other aspects of the embodiments, the electrode 14 can be formed using ALD, the electrode 15 can be formed using ALD, or both the electrodes 14 and 15 can be formed using ALD. As one example, the electrodes 14 and 15 can be formed as thin copper layers using ALD, but other highly conductive layers can be formed using ALD. If ALD is used to form the electrodes 14 and 15, the type of conductive material used to form the electrodes 14 and 15 can be determined in part based on the ALD process available for the material. ALD processes for depositing thin films of pure metal substances, such as pure copper, are known, although additional processes are known for depositing metal alloys.

As noted above, one factor in the material selection for the electrodes 14 and 15 is the desired thickness of the electrodes 14 and 15, which is also a factor in the response characteristics of the BAW resonator 10. For example, if highly conductive and thin electrodes 14 and 15 are desired, then ALD processing can be selected to deposit copper for the electrodes 14 and 15. The electrodes 14 and 15 can also be formed from other metals and metal alloys using ALD processing steps. In other cases, the electrodes 14 and 15 can be formed by sputtering, physical vapor deposition (PVD), chemical vapor deposition (CVD), or related techniques to deposit the conductive material layers for the electrodes 14 and 15. When using a sputtering or other process technique besides ALD, the electrodes 14 and 15 may be relatively thicker. The shapes, sizes, and positions of the electrodes 14 and 15 are representative in FIG. 1. The electrodes 14 and 15 can be formed to have any suitable shape and size.

The thickness of the BAW resonator 10 can be significantly reduced by using ALD to form the layer of piezoelectric material 13 as compared to sputtering. The overall thickness can be further reduced by using ALD to form one or both of the electrodes 14 and 15. The uniformity and conformity of the layer of piezoelectric material 13 and the electrodes 14 and 15 can also be improved by using ALD. As compared to other BAW resonators, the BAW resonator 10 can be tailored by ALD for use in an RF passband filter capable of operation in the 5-20 Ghz range or higher, for steeper stopband attenuation, lower insertion loss, and other improved characteristics. The BAW resonator 10 can also be tailored by ALD for more accurate frequency response, higher quality factor, higher piezoelectric coupling or bandwidth, and smaller temperature coefficient of frequency, among other improved characteristics.

A number of trimming steps may be required after sputtering, but trimming can be reduced or even avoided in many cases when ALD is used. Particularly, a layer of material deposited by sputtering may lack uniformity in thickness to some extent, and trimming is often used to achieve better uniformity in thickness across the surface of a material layer. The lack of uniformity in thickness can be especially pronounced for sputtering when considered across an entire wafer. Trimming can be a relatively costly and time-consuming processing, including the measurement of layer thickness over a wafer, forming a thickness map, and multiple trimming steps using an ion bean or other technique, to smooth the profile of the layer. This trimming process may be needed for both piezoelectric, electrode, and other layers (e.g., temperature compensation layers and/or encapsulation layers) when sputtering or other deposition techniques are relied upon. These trimming steps can be reduced or eliminated in some cases when ALD is used to form the layer of piezoelectric material 13 and the electrodes 14 and 15, saving time and costs. These benefits are even greater when considered over an entire wafer of integrated devices. Other benefits to using ALD processing steps are described below.

Turning to other embodiments, FIG. 2 illustrates an example SAW resonator 20 according to various embodiments described herein. The illustration of the SAW resonator 20 is representative in FIG. 2. The positions, shapes, dimensions, and relative sizes of the layers and features of the SAW resonator 20 are not necessarily drawn to scale in FIG. 2. Example dimensions of the SAW resonator 20 are provided below, but the dimensions of the SAW resonator 20 are not specifically limited. The layers and other features shown in FIG. 2 are also not exhaustive, and the SAW resonator 20 can include other layers, features, and elements that are not separately illustrated. Additionally, the SAW resonator 20 can be formed as part of a larger integrated structure or circuit in combination with other devices and circuit elements. A larger integrated structure of this type may include several resonators similar to the SAW resonator 20, among other integrated components.

The SAW resonator 20 includes a substrate 21, a layer of piezoelectric material 23 over the substrate 21, a first electrode 24, a second electrode 25, a first reflection grating 26, and a second reflection grating 27. The first electrode 24 is positioned over the piezoelectric material 23 and in contact with a first surface (i.e., top surface) of the piezoelectric material 23. The second electrode 25 is also positioned over the piezoelectric material 23 and in contact with a first surface of the piezoelectric material 23. The first electrode 24 and the second electrode 25 include a number of interdigitated fingers, extending laterally next to each other. The first reflection grating 26 and the second reflection grating 27 are positioned at opposite sides of the first electrode 24 and the second electrode 25, as shown.

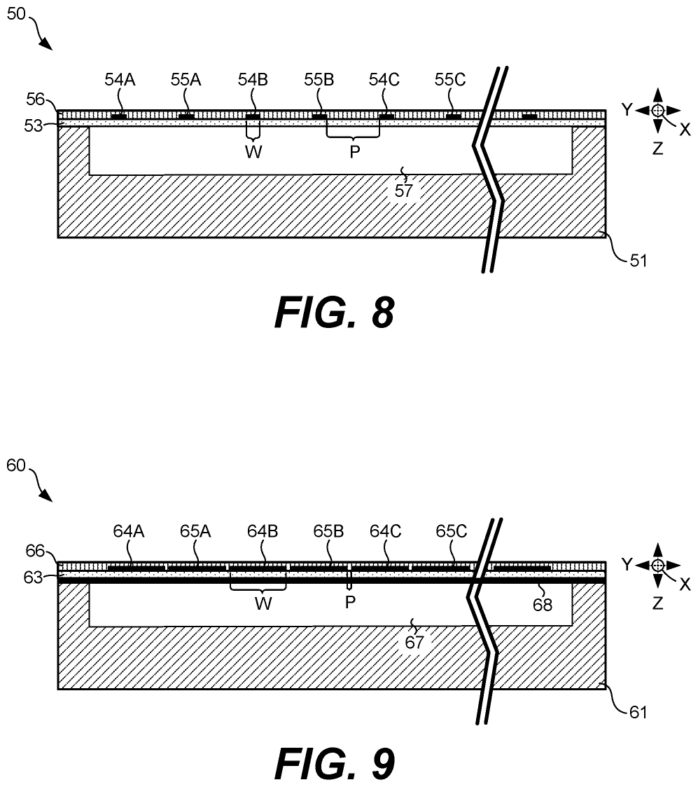

The SAW resonator 20 can also include additional layers described below but not illustrated in FIG. 2, such as a temperature compensation layer, an encapsulation layer, and other others. The SAW resonator 20 can also include an additional structure between the substrate and the layer of piezoelectric material 23 in some cases, such as an acoustic mirror or reflector (e.g., a Bragg reflector). The acoustic mirror or reflector can be relied upon to tailor the operating characteristics of the SAW resonator 20 to account for any unwanted or designed—for BAW-type resonance in the SAW resonator 20. In some cases, the piezoelectric material 23 can be formed to have a crystal structure c-axis orientation in the “X,” “Y,” or “Z” directions, and some BAW-type resonances can be generated using a structure similar to the SAW resonator in some of those cases. Additional examples of such structures are described below with reference to FIGS. 8A and 8B.

Due to the piezoelectric properties of the layer of piezoelectric material 23 and the structural arrangement of the SAW resonator 20, the SAW resonator 20 can generate an acoustic or mechanical wave when an alternating electric potential input signal, such as an RF input, is applied across the electrodes 24 and 25. The acoustic or mechanical wave can travel or translate in the “Y” direction across or along the top surface of the SAW resonator 20, as shown in FIG. 1. The acoustic or mechanical wave can be reflected by the first reflection grating 26 and the second reflection grating 27, according to the operation of the SAW resonator 20.

The substrate 21 can be embodied as a silicon, silicon carbide, lithium niobate, sapphire, glass, ceramic, or another suitable type of substrate for the application. A silicon substrate may be preferred as being relatively low-cost, scalable for manufacturing, and compatible with manufacturing and processing steps, but other substrates can be relied upon.

The electrodes 24 and 25 can be embodied as layers of highly conductive material, such as a metal or metal alloy, including copper, silver, gold, molybdenum, tungsten, titanium, platinum, or aluminum, alloys thereof, and other conductive layers. One factor in the material selection for the electrodes 24 and 25 is the desired thickness of the electrodes 24 and 25, which is also a factor in the response characteristics of the SAW resonator 20. The first reflection grating 26 and the second reflection grating 27 can also be embodied as layers of highly conductive material, such as metals or metal alloys.

The layer of piezoelectric material 23 can be embodied as a layer of PZT, BST, BaTiO3, AlScN, AlN, ZnO, or another piezoelectric material. In one preferred embodiment, the layer of piezoelectric material 23 is a layer of AlN, although other piezoelectric materials can be relied upon. In some cases, the layer of piezoelectric material 23 can include one or more layers of piezoelectric material, including two or more different types of piezoelectric material, each of which is formed using ALD processing techniques according to the embodiments. The piezoelectric material 23 can also include a layer of AlN having a certain crystal orientation. In various embodiments, the layer of AlN can be formed to have a crystal structure c-axis orientation in the “X,” “Y,” or “Z” directions. In one example, the layer of AlN can have a crystal structure c-axis orientation to excite the acoustic or mechanical wave in the “Y” direction across or along the top surface of the SAW resonator 20.

The operating characteristics of the SAW resonator 20, including the frequency response, the accuracy of the frequency response, and the quality factor are determined in part by the conformity and uniformity of the layer of piezoelectric material 23. Although to a lesser extent than for the BAW resonator 10, the operating characteristics of the SAW resonator 20 are also determined in part by the thickness of the layer of piezoelectric material 23. According to one aspect of the embodiments, the layer of piezoelectric material 23 can be embodied as a layer of AlN deposited by ALD. Forming the layer of AlN using ALD rather than sol-gel wet-chemical techniques, sputtering, pulsed laser deposition, or other techniques can result in a layer of piezoelectric material that is more uniform and conformal. Forming the layer of AlN using ALD can also result in a thinner layer of piezoelectric material.

The overall thickness of the layer of piezoelectric material 23 can be determined by the number of ALD cycles used. In some cases, the layer of piezoelectric material 23 can be formed as a thinner layer of piezoelectric material than in conventional SAW resonators, such as when sputtering is used. In one example, the layer of piezoelectric material 23 can be formed as an AlN layer of 100 nm in thickness or less by ALD. The layer of piezoelectric material 23 can be formed to be a thinner layer of AN, however, such as a layer of less than 90 nm, 80 nm, 70 nm, 60 nm, 50 nm, 40 nm, 30 nm, or 20 nm in thickness in some cases using ALD. The layer of piezoelectric material 23 is not limited to a layer of AlN, as other thin films of piezoelectric materials can be formed using ALD.

The specific thickness of the layer of piezoelectric material 23 can be tailored in the SAW resonator 20, sometimes to within less than 10 nm of a target thickness, to within less than 5 nm of a target thickness, or even closer to a target thickness by using ALD. The layer of piezoelectric material 23 can be formed as thin as possible using a minimal number of ALD cycles in some embodiments. The use of ALD rather than sputtering to deposit the layer of piezoelectric material 23 offers a number of advantages. For example, the use of ALD reduces crystal damage in the layer of piezoelectric material 23, reduces dangling bonds, and reduces surface traps commonly attributed to sputter or plasma damage, resulting in better resonator performance.

The thickness, uniformity, and conformality of the other layers in the SAW resonator 20, including the electrodes 24 and 25 and any temperature compensation and encapsulation layers, can be particularly important in the SAW resonator 20. Thus, in other aspects of the embodiments, the electrode 24 can be formed using ALD, the electrode 25 can be formed using ALD, or both the electrodes 24 and 25 can be formed using ALD. As one example, the electrodes 24 and 25 can be formed as thin copper layers using ALD, but other highly conductive layers can be formed using ALD. If ALD is used to form the electrodes 24 and 25, the type of conductive material used to form the electrodes 24 and 25 can be determined in part based on the ALD process available for the material. ALD processes for depositing thin films of pure metal substances, such as pure copper, are known, although additional processes are known for depositing metal alloys. The first reflection grating 26 and the second reflection grating 27 can also be formed using ALD.

The use of ALD to form the electrodes 24 and 25 can be particularly beneficial in the SAW resonator 20, as the acoustic or mechanical wave generated by the SAW resonator 20 travels in the “Y” direction across or along the top surface of the SAW resonator 20 at an interface between the layer of piezoelectric material 23 and the electrodes 24 and 25, as shown in FIG. 2. Thus, the thickness, conformity, and uniformity of the electrodes 24 and 25 can influence or impact the operating characteristics of the SAW resonator 20 more than the thickness, conformity, and uniformity of the electrodes 14 and 15 in the BAW resonator 10. As one example, forming thinner and more uniform electrodes 24 and 25 can help to reduce the effects of unwanted BAW mode resonance in the SAW resonator 20. Additionally, the thickness of any temperature compensation and encapsulation layers formed over the layer of piezoelectric material 23 and the electrodes 24 and 25 can also have a larger impact on the operating characteristics of the SAW resonator 20 than in the BAW resonator 10. Forming thinner and more uniform temperature compensation and encapsulation layers can also help to reduce the effects of unwanted BAW mode resonance in the SAW resonator 20.

One factor in the material selection for the electrodes 24 and 25 is the desired thickness of the electrodes 24 and 25, which is also a factor in the response characteristics of the SAW resonator 20. For example, if highly conductive and thin electrodes 24 and 25 are desired, then ALD processing can be selected to deposit copper for the electrodes 24 and 25. The electrodes 24 and 25 can also be formed from other metals and metal alloys using ALD processing steps. In other cases, the electrodes 24 and 25 can be formed by a sputtering process, PVD, or related techniques to deposit the conductive material layers for the electrodes 24 and 25. When using a sputtering or other process technique besides ALD, the electrodes 24 and 25 may be relatively thicker. The shapes, sizes, and positions of the electrodes 24 and 25 are representative in FIG. 2. The electrodes 24 and 25 can be formed to have any suitable shape and size. In other cases, the first reflection grating 26 and the second reflection grating 27 can be formed by a sputtering process, PVD, or related techniques to deposit the conductive material layers for the reflection gratings 26 and 27. The shapes, sizes, and positions of the reflection gratings 26 and 27 are representative in FIG. 2. The reflection gratings 26 and 27 can be formed to have any suitable shape and size.

The overall thickness of the SAW resonator 20 can be significantly reduced by using ALD to form the layer of piezoelectric material 23 as compared to sputtering. The overall thickness can be further reduced by using ALD to form one or both of the electrodes 24 and 25. The uniformity and conformity of the layer of piezoelectric material 23 and the electrodes 24 and 25 can also be improved by using ALD. As compared to other SAW resonators, the SAW resonator 20 can be tailored by ALD for use in an RF passband filter capable of operation in the 10-20 Ghz range or higher, for steeper stopband attenuation, lower insertion loss, and other improved characteristics. The SAW resonator 20 can also be tailored by ALD for more accurate frequency response, higher quality factor, higher piezoelectric coupling or bandwidth, and smaller temperature coefficient of frequency, among other improved characteristics.

FIG. 3 illustrates an example SMR 30 according to various embodiments described herein, in a cross-sectional view. The illustration of the SMR 30 is representative in FIG. 3. The positions, shapes, dimensions, and relative sizes of the layers and features of the SMR 30 are not necessarily drawn to scale in FIG. 3. Example dimensions of the SMR 30 are provided below, but the dimensions of the SMR 30 are not specifically limited. The layers and other features shown in FIG. 3 are also not exhaustive, and the SMR 30 can include other layers, features, and elements that are not separately illustrated. Additionally, the SMR 30 can be formed as part of a larger integrated structure or circuit in combination with other devices and circuit elements. Such a larger integrated structure may include several resonators similar to the SMR 30, among other integrated components.

The SMR 30 includes a substrate 31, an acoustic mirror 32 over the substrate 31, a layer of piezoelectric material 33 over the substrate 31, a first electrode 34, a second electrode 35, and an encapsulation layer 36. The first electrode 34 is in contact with a first surface (i.e., bottom surface) of the piezoelectric material 33 and positioned at least in part under the piezoelectric material 33, between the piezoelectric material 33 and the substrate 31. The second electrode 35 is in contact with a second surface (i.e., top surface) of the piezoelectric material 33 and positioned at least in part over the piezoelectric material 33. The substrate 31 can be similar to the substrate 11 shown in FIG. 1 and can be embodied as a silicon, silicon carbide, lithium niobate, sapphire, glass, ceramic, or another suitable type of substrate for the application.

The acoustic mirror 32 is one example of the intermediate region 12 in the embodiment shown in FIG. 1. The acoustic mirror 32 can be embodied as a reflector of acoustic waves, such as a Bragg reflector. As one example, the acoustic mirror 32 can be embodied as an odd number of layers of material having high and low acoustic impedance, with the high and low acoustic impedance layers being alternated in the layer stack. In some cases, the acoustic mirror 32 can be formed with ALD, with one or more layers of material in the acoustic mirror 32 being formed with ALD. The thickness of the layers in the stack can be optimized to the quarter wavelength, for example, of the acoustic waves being generated by the SMR 30, to increase acoustic reflectivity. The acoustic mirror 32 provides acoustic isolation between the substrate 31 and the resonator formed by the piezoelectric material 33 and the electrodes 34 and 35.

Due to the piezoelectric properties of the layer of piezoelectric material 33 and the structural arrangement of the SMR 30, the SMR 30 can generate an acoustic or mechanical wave when an alternating electric potential input signal, such as an RF input, is applied across the electrodes 34 and 35. The acoustic or mechanical wave can travel or translate in the “Z” direction, and it can be substantially reflected by the acoustic mirror 32.

The electrodes 34 and 35 can be embodied as layers of highly conductive material, such as a metal or metal alloy, including copper, silver, gold, molybdenum, tungsten, titanium, platinum, or aluminum, alloys thereof, and other conductive layers. The layer of piezoelectric material 33 can be embodied as a layer of PZT, BST, BaTiO3, AlScN, AlN, ZnO, or another piezoelectric material. In one preferred embodiment, the layer of piezoelectric material 33 is a layer of AlN, although other piezoelectric materials can be relied upon. The piezoelectric material 33 can also include a layer of AlN having a certain crystal orientation. In one example, the layer of AlN can have a crystal structure c-axis orientation to excite the acoustic or mechanical wave in the “Z” direction. The encapsulation layer 36 can be embodied as a thin film of material to protect the SMR 30. The encapsulation layer 36 can be a layer of aluminum oxide (Al₂O₃) for example, another oxide material, or another suitable material to protect the SMR 30.

The operating characteristics of the SMR 30, including the frequency response, the accuracy of the frequency response, and the quality factor are determined in part by the thickness, conformity, and uniformity of the layer of piezoelectric material 33. According to one aspect of the embodiments, the layer of piezoelectric material 33 can be embodied as a layer of AlN deposited by ALD. Forming the layer of AlN using ALD rather than sol-gel wet-chemical techniques, sputtering, pulsed laser deposition, or other techniques can result in thinner, more uniform, and more conformal layers of piezoelectric material.

The layer of piezoelectric material 33 can be formed as a thinner layer of piezoelectric material than in conventional SMR resonators, such as when sputtering is used. In one example, the layer of piezoelectric material 33 can be formed as an AlN layer of 100 nm in thickness or less by ALD. The layer of piezoelectric material 33 can be formed to be a thinner layer of AlN, however, such as a layer of less than 90 nm, 80 nm, 70 nm, 60 nm, 50 nm, 40 nm, 30 nm, or 20 nm in thickness in some cases using ALD. The layer of piezoelectric material 33 is not limited to a layer of AlN, as other thin films of piezoelectric materials can be formed using ALD. In some cases, the layer of piezoelectric material 33 can include one or more layers of piezoelectric material, including two or more different types of piezoelectric material (e.g., a stack of two or more of layers of AlN, PZT, BST, BaTiO3, and AlScN), each of which can be formed using ALD processing techniques according to the embodiments.

The specific thickness of the layer of piezoelectric material 33 can be highly controlled or tailored in the SMR 30, sometimes to within less than 10 nm of a target thickness, to within less than 5 nm of a target thickness, or even closer to a target thickness by using ALD. The layer of piezoelectric material 33 can be formed as thin as possible using a minimal number of ALD cycles in some embodiments. The use of ALD rather than sputtering to deposit the layer of piezoelectric material 33 offers a number of advantages. For example, the use of ALD reduces crystal damage in the layer of piezoelectric material 33, reduces dangling bonds, and reduces surface traps commonly attributed to sputter or plasma damage, resulting in better resonator performance.

In other aspects of the embodiments, the electrode 34 can be formed using ALD, the electrode 35 can be formed using ALD, or both the electrodes 34 and 35 can be formed using ALD. As one example, the electrodes 34 and 35 can be formed as thin copper layers using ALD, but other highly conductive layers can be formed using ALD. If ALD is used to form the electrodes 34 and 35, the type of conductive material used to form the electrodes 34 and 35 can be determined in part based on the ALD process available for the material. ALD processes for depositing thin films of pure metal substances, such as pure copper, are known, although additional processes are known for depositing metal alloys.

As noted above, one factor in the material selection for the electrodes 34 and 35 is the desired thickness of the electrodes 34 and 35, which is also a factor in the response characteristics of the SMR 30. For example, if highly conductive and thin electrodes 34 and 35 are desired, then ALD processing can be selected to deposit copper for the electrodes 34 and 35. The electrodes 34 and 35 can also be formed from other metals and metal alloys using ALD processing steps. In other cases, the electrodes 34 and 35 can be formed by a sputtering process, PVD, or related techniques to deposit the conductive material layers for the electrodes 34 and 35. When using a sputtering or other process technique besides ALD, the electrodes 34 and 35 may be relatively thicker. The shapes, sizes, and positions of the electrodes 34 and 35 are representative in FIG. 3. The electrodes 34 and 35 can be formed to have any suitable shape and size.

The encapsulation layer 36 can also be formed using ALD according to one aspect of the embodiments. The encapsulation layer 36 can be formed as a uniform and conformal thin film. In one example, the encapsulation layer 36 can be formed as a layer of Al₂O₃ that is 100 nm or thinner, using ALD. The encapsulation layer 36 can also be formed to be a thinner layer of Al₂O₃, such as a layer of less than 10 nm, 5 nm, or thinner in some cases using ALD. The encapsulation layer 36 is not limited to a layer of Al₂O₃, as other thin films of protective materials can be formed using ALD.

The overall thickness of the SMR 30 can be significantly reduced by using ALD to form the layer of piezoelectric material 33 as compared to sputtering. The overall thickness can be further reduced by using ALD to form one or both of the electrodes 34 and 35 and the encapsulation layer 36. The uniformity and conformity of the layer of piezoelectric material 33, the electrodes 34 and 35, and the encapsulation layer 36 can also be improved by using ALD. As compared to other SMR structures, the SMR 30 can be tailored by ALD for use in an RF passband filter capable of operation in the 5-20 Ghz range or higher, for steeper stopband attenuation, lower insertion loss, and other improved characteristics. The SMR 30 can also be tailored by ALD for more accurate frequency response, higher quality factor, higher piezoelectric coupling or bandwidth, and smaller temperature coefficient of frequency, among other improved characteristics.

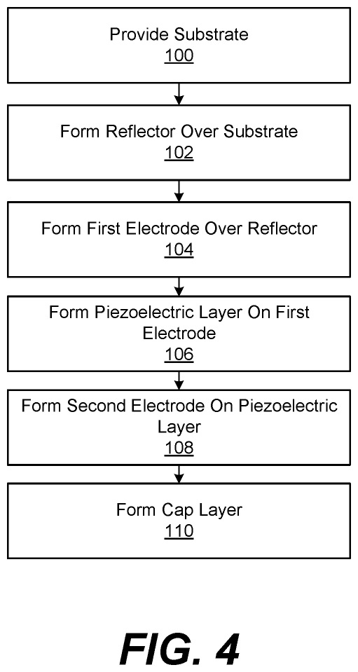

FIG. 4 illustrates an example method of manufacture of the SMR 30 shown in FIG. 3 according to various embodiments described herein. Although the method is described in connection with the SMR 30 shown in FIG. 3, the method can also be relied upon to manufacture solidly mounted resonators similar to that shown in FIG. 3. Additionally, although the method illustrates a specific order of steps in FIG. 4, the order of the steps can differ from that which is depicted. For example, two or more steps shown in succession can be performed, at least in part, at the same time. In some cases, one or more of the steps can be skipped or omitted. In other cases, additional steps not shown in FIG. 4 can be relied upon, such as steps among or after the steps shown in FIG. 4.

At step 100, the process includes providing a substrate for the SMR 30. Referring to the example shown in FIG. 3, the substrate 31 is illustrated as one example of a substrate that can be provided at step 100. The substrate 31 can be embodied as a silicon, silicon carbide, lithium niobate, sapphire, glass, ceramic, or another suitable type of substrate for the application. The substrate 31 can be manufactured, sourced from a vendor, or formed or provided in any other suitable way at step 100.

At step 102, the process includes forming the acoustic mirror 32 over the substrate 31. As one example, the acoustic mirror 32 can be formed as alternating layers of material having high and low acoustic impedance or refractive indexes, such as a Bragg reflector. The acoustic mirror 32 provides acoustic isolation between the substrate 31 and the resonator formed by the piezoelectric material 33 and the electrodes 34 and 35, which are formed in later process steps.

At step 104, the process includes forming the first electrode 34 over the acoustic mirror 32. The first electrode 34 can be embodied as a layer of highly conductive material as described herein. In one example, the electrode 34 can be formed as a thin layer or film of copper using ALD. The electrode 34 can be formed at a thickness of 300 nm, 200 nm, or 100 nm or less using ALD. The electrode 34 can be formed to be a thinner layer of copper, however, such as a layer of less than 90 nm, 80 nm, 70 nm, 60 nm, 50 nm, 40 nm, 30 nm, or 20 nm in thickness in some cases using ALD.

One factor in the selection of the material for the electrode 34 is the desired thickness of the electrode 34, which is also a factor in the response characteristics of the SMR 30. For example, if a highly conductive and thin electrode 34 is needed, then ALD processing can be selected to deposit copper for the electrode 34. The electrode 34 can also be formed from other metals and metal alloys using ALD processing at step 104. In other cases, the electrode 34 can be formed as molybdenum or another metal or metal alloy by sputtering, PVD, CVD, or related techniques at step 104. When using a process technique besides ALD, the electrode 34 may be formed relatively thicker than when using ALD.

At step 106, the process includes depositing the layer of piezoelectric material 33 over the substrate 31 by ALD processing steps. The layer of piezoelectric material 33 can be deposited on the electrode 34 as shown in FIG. 3. The ALD process can be started with an initiation of the surface of the electrode 34 for the deposit of piezoelectric material, such as AlN, on the electrode 34. In a reaction chamber for ALD processing steps, the initiation can include annealing the electrode 34 or the top surface of the electrode 34, etching the electrode 34, exposing the electrode 34 to one or more gases, or other steps to remove contaminants from the top surface of the electrode 34 or otherwise prepare the surface of the electrode 34 for the deposit of materials. The crystal orientation of the layer of piezoelectric material 33 can also be directed at step 106. For example, the initiation can be tailored to form the layer of piezoelectric material 33 having a crystal structure c-axis orientation for acoustic or mechanical waves in the “Z” direction shown in FIG. 3.

After initiation, the ALD process at step 106 can proceed with the exposure of the electrode 34 to two or more precursor chemicals or reactants, in a repeating sequence. The precursors can be gaseous species introduced to an ALD chamber separately over time. The precursors react, respectively in time, in a self-limiting way. Any excess or remaining reactant of a precursor is flushed away before the next precursor or ALD cycle is applied or repeated. ALD processes are characterized by both dose times, which are the times that the surface is exposed to a respective precursor, and purge times, which are the times between doses during which the ALD chamber is evacuated for the next step. For a two reactant ALD process, a first reactant dose, first purge, second reactant dose, second purge sequence are steps in one ALD cycle.

For the first reactant dose cycle, a first precursor can be introduced into the ALD reaction chamber, which exposes the top surface of the electrode 34 to the first precursor, with the application of heat. The time for the first reactant dose cycle can be selected to saturate the top surface of the electrode 34 with the first precursor. The ALD reaction chamber can then be purged in a first purge cycle to remove any byproducts of the first reactant dose cycle. The ALD reaction chamber can be purged by introducing an inert gas, for example, evacuated using a vacuum, or by other steps.

For the second reactant dose cycle, a second precursor can be introduced into the ALD reaction chamber. The time for the second reactant dose cycle can be sufficient for the second precursor to fully or substantially react with the first precursor, until sites for the reaction between the precursors are exhausted. The ALD reaction chamber can then be purged in a second purge cycle to remove any byproducts of the second reactant dose cycle. The ALD reaction chamber can be purged by introducing an inert gas, for example, evacuated using a vacuum, or by other steps. Then, another ALD cycle can begin.

The thickness of the layer of piezoelectric material 33 can be determined by the number of ALD cycles used at step 106, and the number of cycles can be tailored to grow the layer of piezoelectric material 33 in a uniform and conformal way, with very high precision. In one example, the layer of piezoelectric material 33 can be formed as an AlN layer of 100 nm in thickness or less by ALD. The layer of piezoelectric material 33 can be formed to be a thinner layer of AlN, however, such as a layer of less than 90 nm, 80 nm, 70 nm, 60 nm, 50 nm, 40 nm, 30 nm, or 20 nm in thickness in some cases using ALD at step 106. The layer of piezoelectric material 33 is also not limited to a layer of AlN, as other thin films of piezoelectric materials can be formed using ALD at step 106.

In some cases, step 106 can also include trimming the layer of piezoelectric material 33, to further improve the uniformity of the layer, tailor the thickness of the layer, or otherwise modify the layer of piezoelectric material 33. Although trimming can be a relatively costly and time-consuming processing, any trimming performed at step 106 can be relatively minor as compared to if sputtering were used to form the layer of piezoelectric material 33.

At step 108, the process includes forming the second electrode 35 on the layer of piezoelectric material 33. The second electrode 35 can be embodied as a layer of highly conductive material as described herein. In one example, the electrode 35 can be formed as a thin layer or film of copper using ALD. The electrode 35 can be formed at a thickness of 300 nm, 200 nm, or 100 nm or less using ALD. The electrode 35 can be formed to be a thinner layer of copper, however, such as a layer of less than 90 nm, 80 nm, 70 nm, 60 nm, 50 nm, 40 nm, 30 nm, or 20 nm in thickness in some cases using ALD.

One factor in the selection of the material for the electrode 35 is the desired thickness of the electrode 35, which is also a factor in the response characteristics of the SMR 30. For example, if a highly conductive and thin electrode 35 is needed, then ALD processing can be selected to deposit copper for the electrode 35. The electrode 35 can also be formed from other metals and metal alloys using ALD processing at step 108. In other cases, the electrode 35 can be formed as molybdenum or another metal or metal alloy by sputtering, PVD, CVD, or related techniques at step 108. When using a process technique besides ALD, the electrode 35 may be formed relatively thicker than when using ALD.

At step 110, the process includes forming the encapsulation layer 36. The encapsulation layer 36 can be formed as a uniform and conformal thin film. In one example, the encapsulation layer 36 can be formed as a layer of Al₂O₃ that is 100 nm or thinner, by ALD processing steps. The encapsulation layer 36 can also be formed to be a thinner layer of Al₂O₃, such as a layer of less than 10 nm, 5 nm, or thinner in some cases using ALD. The encapsulation layer 36 is not limited to a layer of Al₂O₃, as other thin films of protective materials can be formed using ALD.

As compared to other deposition processes, the encapsulation layer 36 can be formed very thin using ALD, to tailor the frequency response, the accuracy of the frequency response, the quality factor, and the insertion losses of the SMR 30. The encapsulation layer 36 can cover and encapsulate the layer of piezoelectric material 33, the first electrode 34, and the second electrode 35, as shown in FIG. 3. In some cases, the encapsulation layer 36 can cover more or less of an area as compared to that shown in FIG. 3.

In some cases, the process shown in FIG. 4 can include additional steps, such as forming one or more temperature compensation layers in the SMR 30. For example, the process can include forming a temperature compensation layer, such as a layer of silicon dioxide (SiO2) or other material for temperature compensation, between steps 104 and 106. In that case, a layer of SiO2 can be formed between the first electrode 34 and the piezoelectric material 33 using ALD, and the first electrode can be formed on the temperature compensation rather than on the piezoelectric material 33. A layer of SiO2 can also be formed between steps 106 and 108, between the piezoelectric material 33 and the second electrode 35 using ALD. Due to the use of ALD processing steps, the temperature compensation layer or layers can be more uniform, more conformal, and thinner than they would be if formed using other deposition techniques. As some examples, the layer of SiO2 can be formed to be a layer of less than 90 nm, 80 nm, 70 nm, 60 nm, 50 nm, 40 nm, 30 nm, or 20 nm in thickness.

FIG. 5 illustrates an example FBAR 40 according to various embodiments described herein. The illustration of the FBAR 40 is representative in FIG. 5. The positions, shapes, dimensions, and relative sizes of the layers and features of the FBAR 40 are not necessarily drawn to scale in FIG. 5. Example dimensions of the FBAR 40 are provided below, but the dimensions of the FBAR 40 are not specifically limited. The layers and other features shown in FIG. 5 are also not exhaustive, and the FBAR 40 can include other layers, features, and elements that are not separately illustrated. Additionally, the FBAR 40 can be formed as part of a larger integrated structure or circuit in combination with other devices and circuit elements. Such a larger integrated structure may include several resonators similar to the FBAR 40, among other integrated components.

The FBAR 40 includes a substrate 41, a supporting layer 42 over the substrate 41, a layer of piezoelectric material 43 over the substrate 41, a first electrode 44, a second electrode 45, an encapsulation layer 46, and an isolation cavity 47. The first electrode 44 is in contact with a first surface (i.e., bottom surface) of the piezoelectric material 43 and positioned at least in part under the piezoelectric material 43, between the piezoelectric material 43 and the substrate 41. The second electrode 45 is in contact with a second surface (i.e., top surface) of the piezoelectric material 43 and positioned at least in part over the piezoelectric material 43. The substrate 41 can be similar to the substrate 11 shown in FIG. 1 and can be embodied as a silicon, silicon carbide, lithium niobate, sapphire, glass, ceramic, or another suitable type of substrate for the application.

The supporting layer 42 is one example of the intermediate region 12 in the embodiment shown in FIG. 1. The supporting layer 42 can be embodied as a layer of supporting material, such as silicon, formed over the substrate 41. The supporting layer 42 supports the resonator formed by the piezoelectric material 43 and the electrodes 44 and 45, as further described below.

Due to the piezoelectric properties of the layer of piezoelectric material 43 and the structural arrangement of the FBAR 40, FBAR 40 can generate an acoustic or mechanical wave when an alternating electric potential input signal, such as an RF input, is applied across the electrodes 44 and 45. The acoustic or mechanical wave can travel or translate in the “Z” direction, and it can be isolated by the isolation cavity 47, as also described below.

The electrodes 44 and 45 can be embodied as layers of highly conductive material, such as a metal or metal alloy, including copper, silver, gold, molybdenum, tungsten, titanium, platinum, or aluminum, alloys thereof, and other conductive layers. The layer of piezoelectric material 43 can be embodied as a layer of PZT, BST, BaTiO3, AlScN, AlN, ZnO, or another piezoelectric material. In one preferred embodiment, the layer of piezoelectric material 43 is a layer of AlN, although other piezoelectric materials can be relied upon. The piezoelectric material 43 can also include a layer of AlN having a certain crystal orientation. In one example, the layer of AlN can have a crystal structure c-axis orientation to excite the acoustic or mechanical wave in the “Z” direction. The encapsulation layer 46 can be embodied as a thin film of material to protect the FBAR 40. The encapsulation layer 46 can be a layer of Al₂O₃ for example, another oxide material, or another suitable material to protect the FBAR 40.

The operating characteristics of the FBAR 40, including the frequency response, the accuracy of the frequency response, and the quality factor are determined in part by the thickness, conformity, and uniformity of the layer of piezoelectric material 43. According to one aspect of the embodiments, the layer of piezoelectric material 43 can be embodied as a layer of AlN deposited by ALD. Forming the layer of AlN using ALD rather than sol-gel wet-chemical techniques, sputtering, pulsed laser deposition, or other techniques can result in thinner, more uniform, and more conformal layers of piezoelectric material.

The layer of piezoelectric material 43 can be formed as a thinner layer of piezoelectric material than in conventional FBAR resonators, such as when sputtering is used. In one example, the layer of piezoelectric material 43 can be formed as an AlN layer of 100 nm in thickness or less by ALD. The layer of piezoelectric material 43 can be formed to be a thinner layer of AlN, however, such as a layer of less than 90 nm, 80 nm, 70 nm, 60 nm, 50 nm, 40 nm, 30 nm, or 20 nm in thickness in some cases using ALD. The layer of piezoelectric material 43 is not limited to a layer of AlN, as other thin films of piezoelectric materials can be formed using ALD. In some cases, the layer of piezoelectric material 43 can include one or more layers of piezoelectric material, including two or more different types of piezoelectric material (e.g., a stack of two or more of layers of AlN, PZT, BST, BaTiO3, and AlScN), each of which can be formed using ALD processing techniques according to the embodiments.

The specific thickness of the layer of piezoelectric material 43 can be highly controlled or tailored in the FBAR 40, sometimes to within less than 10 nm of a target thickness, to within less than 5 nm of a target thickness, or even closer to a target thickness by using ALD. The layer of piezoelectric material 43 can be formed as thin as possible using a minimal number of ALD cycles in some embodiments. The use of ALD rather than sputtering to deposit the layer of piezoelectric material 43 offers a number of advantages. For example, the use of ALD reduces crystal damage in the layer of piezoelectric material 43, reduces dangling bonds, and reduces surface traps commonly attributed to sputter or plasma damage, resulting in better resonator performance.

In other aspects of the embodiments, the electrode 44 can be formed using ALD, the electrode 45 can be formed using ALD, or both the electrodes 44 and 45 can be formed using ALD. As one example, the electrodes 44 and 45 can be formed as thin copper layers using ALD, but other highly conductive layers can be formed using ALD. If ALD is used to form the electrodes 44 and 45, the type of conductive material used to form the electrodes 44 and 45 can be determined in part based on the ALD process available for the material. One factor in the material selection for the electrodes 44 and 45 is the desired thickness of the electrodes 44 and 45, which is also a factor in the response characteristics of the FBAR 40. For example, if very thin and conductive electrodes 44 and 45 are desired, then ALD processing can be selected to deposit copper for the electrodes 44 and 45. In other cases, the electrodes 44 and 45 can be formed by a sputtering process, PVD, or related techniques. When using a sputtering or other process technique besides ALD, the electrodes 44 and 45 may be relatively thicker.

The encapsulation layer 46 can also be formed using ALD according to one aspect of the embodiments. The encapsulation layer 46 can be formed as a uniform and conformal thin film. In one example, the encapsulation layer 46 can be formed as a layer of Al₂O₃ that is 100 nm or thinner, using ALD. The encapsulation layer 46 can also be formed to be a thinner layer of Al₂O₃, such as a layer of less than 10 nm, 5 nm, or thinner in some cases using ALD. The encapsulation layer 46 is not limited to a layer of Al₂O₃, as other thin films of protective materials can be formed using ALD.

The isolation cavity 47 is a space or cavity formed under the supporting layer 42, the layer of piezoelectric material 43, and the electrodes 44 and 45. The isolation cavity 47 can vary in size and proportions as compared to that shown in FIG. 5. In some cases, the isolation cavity 47 can be wider than that shown in FIG. 5, and the isolation cavity 47 can be larger (i.e., in a top-down view of length and width dimensions) than the layer of piezoelectric material 43. In other cases, at least a portion of the layer of piezoelectric material 43 can extend over the substrate 41, beyond the isolation cavity 47, as shown in FIG. 5.

The isolation cavity 47 can be formed by etching or other material-removal process steps, typically after the supporting layer 42 and other layers of the FBAR 40 are formed. In some cases, the isolation cavity 47 can be formed with one or more supporting pillars 48 remaining in the isolation cavity 47. The substrate 41 can be selectively etched to form the isolation cavity, such that the supporting pillars 48 remain in the isolation cavity 47. The supporting pillars 48 can provide additional support to the supporting layer 42. The number and positions of the supporting pillars 48 can vary as compared to that shown in FIG. 5, and the supporting pillars 48 can be omitted in some cases.

The overall thickness of the FBAR 40 can be significantly reduced by using ALD to form the layer of piezoelectric material 43 as compared to sputtering. The overall thickness can be further reduced by using ALD to form one or both of the electrodes 44 and 45 and the encapsulation layer 46. The uniformity and conformity of the layer of piezoelectric material 43, the electrodes 44 and 45, and the encapsulation layer 46 can also be improved by using ALD. As compared to other FBAR structures, the FBAR 40 can be tailored by ALD for use in an RF passband filter capable of operation in the 10-20 Ghz range or higher, for steeper stopband attenuation, lower insertion loss, and other improved characteristics. The FBAR 40 can also be tailored by ALD for more accurate frequency response, higher quality factor, higher piezoelectric coupling or bandwidth, and smaller temperature coefficient of frequency, among other improved characteristics.

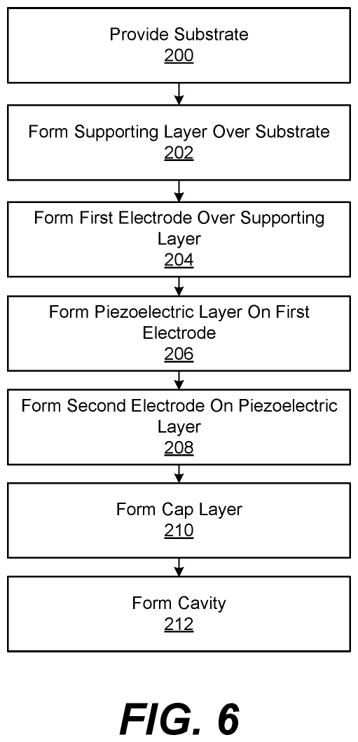

FIG. 6 illustrates an example method of manufacture of the example FBAR 40 shown in FIG. 5 according to various embodiments described herein. Although the method is described in connection with the FBAR 40 shown in FIG. 5, the method can also be relied upon to manufacture thin-film bulk acoustic resonators similar to that shown in FIG. 5. Additionally, although the method illustrates a specific order of steps in FIG. 6, the order of the steps can differ from that which is depicted. For example, two or more steps shown in succession can be performed, at least in part, at the same time. In some cases, one or more of the steps can be skipped or omitted. In other cases, additional steps not shown in FIG. 6 can be relied upon, such as steps among or after the steps shown in FIG. 6.

At step 200, the process includes providing a substrate for the FBAR 40. Referring to the example shown in FIG. 5, the substrate 41 is illustrated as one example of a substrate that can be provided at step 200. The substrate 41 can be embodied as a silicon, silicon carbide, lithium niobate, sapphire, glass, ceramic, or another suitable type of substrate for the application. The substrate 41 can be manufactured, sourced from a vendor, or formed or provided in any other suitable way at step 200.

At step 202, the process includes forming the supporting layer 42 over the substrate 41. As one example, the supporting layer 42 can be embodied as a layer of supporting material, such as silicon, formed over the substrate 41. The supporting layer 42 can be deposited using a suitable deposition technique, such as PVD, CVD, or a related technique. The supporting layer 42 can be formed to any suitable thickness, and it is not necessary that the supporting layer 42 be formed as a thin film. The supporting layer 42 supports the resonator formed by the piezoelectric material 43 and the electrodes 44 and 45, as further described below.

At step 204, the process includes forming the first electrode 44 over the supporting layer 42. The first electrode 44 can be embodied as a layer of highly conductive material as described herein. In one example, the electrode 44 can be formed as a thin layer or film of copper using ALD. The electrode 44 can be formed at a thickness of 300 nm, 200 nm, or 100 nm or less using ALD. The electrode 44 can be formed to be a thinner layer of copper, however, such as a layer of less than 90 nm, 80 nm, 70 nm, 60 nm, 50 nm, 40 nm, 30 nm, or 20 nm in thickness in some cases using ALD.

One factor in the selection of the material for the electrode 44 is the desired thickness of the electrode 44, which is also a factor in the response characteristics of the FBAR 40. For example, if a highly conductive and thin electrode 44 is needed, then ALD processing can be selected to deposit copper for the electrode 44. The electrode 44 can also be formed from other metals and metal alloys using ALD processing at step 204. In other cases, the electrode 44 can be formed as molybdenum or another metal or metal alloy by sputtering, PVD, CVD, or related techniques at step 204. When using a process technique besides ALD, the electrode 34 may be formed relatively thicker than when using ALD.

At step 206, the process includes depositing the layer of piezoelectric material 43 over the substrate 41 by ALD processing steps. The layer of piezoelectric material 43 can be deposited on the electrode 44 as shown in FIG. 5. The ALD process can be started with an initiation of the surface of the electrode 44 for the deposit of piezoelectric material, such as AlN, on the electrode 44. In a reaction chamber for ALD processing steps, the initiation can include annealing the electrode 44 or the top surface of the electrode 44, etching the electrode 44, exposing the electrode 44 to one or more gases, or other steps to remove contaminants from the top surface of the electrode 44 or otherwise prepare the surface of the electrode 44 for the deposit of materials. The crystal orientation of the layer of piezoelectric material 43 can also be directed at step 206. For example, the initiation can be tailored to form the layer of piezoelectric material 43 having a crystal structure c-axis orientation for acoustic or mechanical waves in the “Z” direction shown in FIG. 5.

After initiation, the ALD process at step 206 can proceed with the exposure of the electrode 44 to two or more precursor chemicals or reactants, in a repeating sequence. The precursors can be gaseous species introduced to an ALD chamber separately over time. The precursors react, respectively in time, in a self-limiting way. Any excess or remaining reactant of a precursor is flushed away before the next precursor or ALD cycle is applied or repeated. ALD processes are characterized by both dose times, which are the times that the surface is exposed to a respective precursor, and purge times, which are the times between doses during which the ALD chamber is evacuated for the next step. For a two reactant ALD process, a first reactant dose, first purge, second reactant dose, second purge sequence are steps in one ALD cycle.

For the first reactant dose cycle, a first precursor can be introduced into the ALD reaction chamber, which exposes the top surface of the electrode 44 to the first precursor, with the application of heat. The time for the first reactant dose cycle can be selected to saturate the top surface of the electrode 44 with the first precursor. The ALD reaction chamber can then be purged in a first purge cycle to remove any byproducts of the first reactant dose cycle. The ALD reaction chamber can be purged by introducing an inert gas, for example, evacuated using a vacuum, or by other steps.

For the second reactant dose cycle, a second precursor can be introduced into the ALD reaction chamber. The time for the second reactant dose cycle can be sufficient for the second precursor to fully or substantially react with the first precursor, until sites for the reaction between the precursors are exhausted. The ALD reaction chamber can then be purged in a second purge cycle to remove any byproducts of the second reactant dose cycle. The ALD reaction chamber can be purged by introducing an inert gas, for example, evacuated using a vacuum, or by other steps. Then, another ALD cycle can begin.

The thickness of the layer of piezoelectric material 43 can be determined by the number of ALD cycles used at step 206, and the number of cycles can be tailored to grow the layer of piezoelectric material 43 in a uniform and conformal way, with very high precision. In one example, the layer of piezoelectric material 43 can be formed as an AlN layer of 100 nm in thickness or less by ALD. The layer of piezoelectric material 43 can be formed to be a thinner layer of AlN, however, such as a layer of less than 90 nm, 80 nm, 70 nm, 60 nm, 50 nm, 40 nm, 30 nm, or 20 nm in thickness in some cases using ALD at step 206. The layer of piezoelectric material 43 is also not limited to a layer of AlN, as other thin films of piezoelectric materials can be formed using ALD at step 206.

In some cases, step 206 can also include trimming the layer of piezoelectric material 43, to further improve the uniformity of the layer, tailor the thickness of the layer, or otherwise modify the layer of piezoelectric material 43. Although trimming can be a relatively costly and time-consuming processing, any trimming performed at step 206 can be relatively minor as compared to if sputtering were used to form the layer of piezoelectric material 43.

At step 208, the process includes forming the second electrode 45 on the layer of piezoelectric material 43. The second electrode 45 can be embodied as a layer of highly conductive material as described herein. In one example, the electrode 45 can be formed as a thin layer or film of copper using ALD. The electrode 45 can be formed at a thickness of 300 nm, 200 nm, or 100 nm or less using ALD. The electrode 45 can be formed to be a thinner layer of copper, however, such as a layer of less than 90 nm, 80 nm, 70 nm, 60 nm, 50 nm, 40 nm, 30 nm, or 20 nm in thickness in some cases using ALD.

One factor in the selection of the material for the electrode 45 is the desired thickness of the electrode 45, which is also a factor in the response characteristics of the FBAR 40. For example, if a highly conductive and thin electrode 45 is needed, then ALD processing can be selected to deposit copper for the electrode 45. The electrode 45 can also be formed from other metals and metal alloys using ALD processing at step 208. In other cases, the electrode 45 can be formed as molybdenum or another metal or metal alloy by sputtering, PVD, CVD, or related techniques at step 208. When using a process technique besides ALD, the electrode 45 may be formed relatively thicker than when using ALD.

At step 210, the process includes forming the encapsulation layer 46. The encapsulation layer 46 can be formed as a uniform and conformal thin film. In one example, the encapsulation layer 46 can be formed as a layer of Al₂O₃ that is 100 nm or thinner, by ALD processing steps. The encapsulation layer 46 can also be formed to be a thinner layer of Al₂O₃, such as a layer of less than 10 nm, 5 nm, or thinner in some cases using ALD. The encapsulation layer 46 is not limited to a layer of Al₂O₃, as other thin films of protective materials can be formed using ALD.

As compared to other deposition processes, the encapsulation layer 46 can be formed very thin using ALD, to tailor the frequency response, the accuracy of the frequency response, the quality factor, and the insertion losses of the FBAR 40. The encapsulation layer 46 can cover and encapsulate the layer of piezoelectric material 43, the first electrode 44, and the second electrode 45, as shown in FIG. 5. In some cases, the encapsulation layer 46 can cover more or less of an area as compared to that shown in FIG. 4.

At step 212, the process includes forming the isolation cavity 47 under the supporting layer 42, the layer of piezoelectric material 43, and the electrodes 44 and 45. The isolation cavity 47 can be formed to any suitable size for the purpose of isolating the acoustic waves generated by the layer of piezoelectric material 43. In some cases, the isolation cavity 47 can be wider than that shown in FIG. 5, and the isolation cavity 47 can be larger (i.e., in a top-down view of length and width dimensions) than the layer of piezoelectric material 43. In other cases, at least a portion of the layer of piezoelectric material 43 can extend over the substrate 41, beyond the isolation cavity 47, as shown in FIG. 5. The isolation cavity 47 can be formed by etching or other material-removal process steps. In some cases, the isolation cavity 47 can be formed with one or more supporting pillars 48 (FIG. 5) remaining in the isolation cavity 47 to provide additional support to the supporting layer 42. The number and positions of the supporting pillars 48 can vary as compared to that shown in FIG. 5, and the supporting pillars 48 can be omitted in some cases.

In some cases, the process shown in FIG. 6 can include additional steps, such as forming one or more temperature compensation layers in the FBAR 40. For example, the process can include forming a temperature compensation layer, such as a layer of SiO2 or other material for temperature compensation, between steps 204 and 206. In that case, a layer of SiO2 can be formed between the first electrode 44 and the piezoelectric material 43 using ALD. A layer of SiO2 can also be formed between steps 206 and 208, between the piezoelectric material 43 and the second electrode 45 using ALD. Due to the use of ALD processing steps, the temperature compensation layer or layers can be more uniform, more conformal, and thinner than they would be if formed using other deposition techniques. As some examples, the layer of SiO2 can be formed to be a layer of less than 90 nm, 80 nm, 70 nm, 60 nm, 50 nm, 40 nm, 30 nm, or 20 nm in thickness.

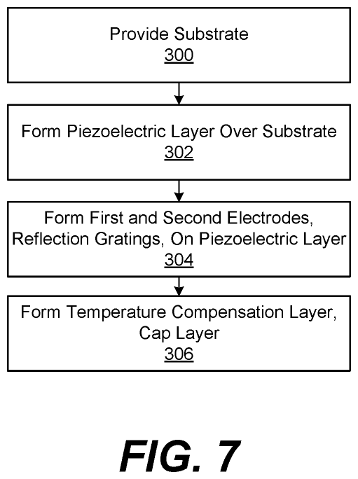

FIG. 7 illustrates an example method of manufacture of the SAW resonator 20 shown in FIG. 2 according to various embodiments described herein. Although the method is described in connection with the SAW resonator 20 shown in FIG. 2, the method can also be relied upon to manufacture SAW resonators similar to that shown in FIG. 2. Additionally, although the method illustrates a specific order of steps in FIG. 7, the order of the steps can differ from that which is depicted. For example, two or more steps shown in succession can be performed, at least in part, at the same time. In some cases, one or more of the steps can be skipped or omitted. In other cases, additional steps not shown in FIG. 7 can be relied upon, such as steps among or after the steps shown in FIG. 7.

At step 300, the process includes providing a substrate for the SAW resonator 20. Referring to the example shown in FIG. 2, the substrate 21 is illustrated as one example of a substrate that can be provided at step 300. The substrate 21 can be embodied as a silicon, silicon carbide, lithium niobate, sapphire, glass, ceramic, or another suitable type of substrate for the application. The substrate 21 can be manufactured, sourced from a vendor, or formed or provided in any other suitable way at step 300.

At step 302, the process includes depositing the layer of piezoelectric material 23 over the substrate 21 by ALD processing steps. The ALD process can be started with an initiation of the surface of substrate 21 for the deposit of piezoelectric material, such as AlN, on the substrate 21. Ina reaction chamber for ALD processing steps, the initiation can include etching the substrate 21, exposing the substrate 21 to one or more gases, or other steps to remove contaminants from the top surface of the substrate 21 or otherwise prepare the surface of the substrate 21 for the deposit of materials. The crystal orientation of the layer of piezoelectric material 23 can also be directed at step 302. For example, the initiation can be tailored to form the layer of piezoelectric material 23 having a crystal structure c-axis orientation for acoustic or mechanical waves in the “Y” direction shown in FIG. 2.

After initiation, the ALD process at step 302 can proceed with the exposure of the substrate 21 to two or more precursor chemicals or reactants, in a repeating sequence. The precursors can be gaseous species introduced to an ALD chamber separately over time. The precursors react, respectively in time, in a self-limiting way. Any excess or remaining reactant of a precursor is flushed away before the next precursor or ALD cycle is applied or repeated. ALD processes are characterized by both dose times, which are the times that the surface is exposed to a respective precursor, and purge times, which are the times between doses during which the ALD chamber is evacuated for the next step. For a two reactant ALD process, a first reactant dose, first purge, second reactant dose, second purge sequence are steps in one ALD cycle.

For the first reactant dose cycle, a first precursor can be introduced into the ALD reaction chamber, which exposes the top surface of the substrate 21 to the first precursor, with the application of heat. The time for the first reactant dose cycle can be selected to saturate the top surface of the substrate 21 with the first precursor. The ALD reaction chamber can then be purged in a first purge cycle to remove any byproducts of the first reactant dose cycle. The ALD reaction chamber can be purged by introducing an inert gas, for example, evacuated using a vacuum, or by other steps.

For the second reactant dose cycle, a second precursor can be introduced into the ALD reaction chamber. The time for the second reactant dose cycle can be sufficient for the second precursor to fully or substantially react with the first precursor, until sites for the reaction between the precursors are exhausted. The ALD reaction chamber can then be purged in a second purge cycle to remove any byproducts of the second reactant dose cycle. The ALD reaction chamber can be purged by introducing an inert gas, for example, evacuated using a vacuum, or by other steps. Then, another ALD cycle can begin.

The thickness of the layer of piezoelectric material 23 can be determined by the number of ALD cycles used at step 302, and the number of cycles can be tailored to grow the layer of piezoelectric material 23 in a uniform and conformal way, with very high precision. In one example, the layer of piezoelectric material 23 can be formed as an AlN layer of 100 nm in thickness or less by ALD. The layer of piezoelectric material 23 can be formed to be a thinner layer of AlN, however, such as a layer of less than 90 nm, 80 nm, 70 nm, 60 nm, 50 nm, 40 nm, 30 nm, or 20 nm in thickness in some cases using ALD at step 206. The layer of piezoelectric material 23 is also not limited to a layer of AlN, as other thin films of piezoelectric materials can be formed using ALD at step 302.

In some cases, step 302 can also include trimming the layer of piezoelectric material 23, to further improve the uniformity of the layer, tailor the thickness of the layer, or otherwise modify the layer of piezoelectric material 23. Although trimming can be a relatively costly and time-consuming processing, any trimming performed at step 306 can be relatively minor as compared to if sputtering were used to form the layer of piezoelectric material 23.

At step 304, the process includes forming the first electrode 24, the second electrode 25, and the reflection gratings 26 and 27 on the layer of piezoelectric material 23. The electrodes 24 and 25 can be embodied as layers of highly conductive material. In one example, the electrodes 24 and 25 can be formed as thin layers or films of copper using ALD. The electrodes 24 and 25 can be formed at a thickness of 300 nm, 200 nm, or 100 nm or less using ALD. The electrodes 24 and 25 can be formed to be a thinner layer of copper, however, such as a layer of less than 90 nm, 80 nm, 70 nm, 60 nm, 50 nm, 40 nm, 30 nm, or 20 nm in thickness in some cases using ALD. The reflection gratings 26 and 27 can be omitted in some cases. When included, the reflection gratings 26 and 27 can also be formed using ALD, at the same or similar thickness as the electrodes 24 and 25.

One factor in the selection of the material for the electrodes 24 and 25 is the desired thickness of the electrodes 24 and 25, which is also a factor in the response characteristics of the SAW resonator 20. For example, if highly conductive and thin electrodes 24 and 25 are needed, then ALD processing can be selected to deposit copper for the electrodes 24 and 25. The electrodes 24 and 25 can also be formed from other metals and metal alloys using ALD processing at step 304. In other cases, the electrodes 24 and 25 can be formed as molybdenum or another metal or metal alloy by sputtering, PVD, CVD, or related techniques at step 304. When using a process technique besides ALD, the electrodes 24 and 25 may be formed relatively thicker than when using ALD.

At step 306, the process includes forming an encapsulation layer over the electrodes 24 and 25, the reflection gratings 26 and 27, and the layer of piezoelectric material 23. Although an encapsulation layer is not shown in FIG. 2, an encapsulation layer similar to the encapsulation layers 36 and 46 shown in FIGS. 3 and 5 can be formed as a uniform and conformal thin film over the electrodes 24 and 25, the reflection gratings 26 and 27, and the layer of piezoelectric material 23. The encapsulation layer 46 can be formed as a layer of Al₂O₃ that is 100 nm or thinner, by ALD processing steps. The encapsulation layer 46 can also be formed to be a thinner layer of Al₂O₃, such as a layer of less than 10 nm, 5 nm, or thinner in some cases using ALD. The encapsulation layer 46 is not limited to a layer of Al₂O₃, as other thin films of protective materials can be formed using ALD.

The structures and methods described herein can be used to fabricate a wide variety of useful integrated circuits. For example, the acoustic resonators described herein can be integrated with various components in a monolithic circuit format suitable for microwave circuit applications. Although embodiments have been described herein in detail, the descriptions, including the dimensions states, are by way of example.

In some cases, the process shown in FIG. 7 can include additional steps, such as forming one or more temperature compensation layers in the SAW resonator 20. For example, the process can include forming a temperature compensation layer, such as a layer of SiO2 or other material for temperature compensation, between steps 302 and 304. In that case, a layer of SiO2 can be formed between the layer of piezoelectric material 23 and the electrodes 24 and 25 using ALD. Due to the use of ALD processing steps, the temperature compensation layer or layers can be more uniform, more conformal, and thinner than they would be if formed using other deposition techniques. As some examples, the layer of SiO2 can be formed to be a layer of less than 90 nm, 80 nm, 70 nm, 60 nm, 50 nm, 40 nm, 30 nm, or 20 nm in thickness.

FIG. 8 is a cross-sectional view of an example laterally-excited bulk acoustic wave resonator 50 (“resonator 50”) according to various embodiments described herein. The illustration of the resonator 50 is representative in FIG. 8. The positions, shapes, dimensions, and relative sizes of the layers and features of the resonator 50 are not necessarily drawn to scale in FIG. 8. Example dimensions of the resonator 50 are provided below, but the dimensions are not specifically limited. The layers and other features shown in FIG. 8 are also not exhaustive, and the resonator 50 can include other layers, features, and elements that are not separately illustrated. Additionally, the resonator 50 can be formed as part of a larger integrated structure or circuit in combination with other devices and circuit elements. Such a larger integrated structure may include several resonators similar to the resonator 50, among other integrated components.

The resonator 50 includes a substrate 51, a layer of piezoelectric material 53 over the substrate 51, first electrodes 54A-54C interdigitated with second electrodes 55A-55C, an encapsulation layer 56, and an isolation cavity 57. The interdigitated electrodes 54A-54C and 55A-55C are similar to the interdigitated electrodes 24 and 25 shown in FIG. 2, although a cross section of the electrodes 54A-54C and 55A-55C is shown in FIG. 8. A limited number of the electrodes 54A-54C and 55A-55C are shown in FIG. 8, but it should be appreciated that a larger number of electrodes can be relied upon in practice. The electrodes 54A-54C and 55A-55C are in contact with a top surface of the piezoelectric material 53. The substrate 51 can be similar to the substrate 11 shown in FIG. 1 and can be embodied as a silicon, silicon carbide, lithium niobate, sapphire, glass, ceramic, or another suitable type of substrate for the application. Although not shown in FIG. 8, the resonator 50 can also include a supporting layer similar to the supporting layer 42 in FIG. 5 in some cases. Such a layer of supporting material can be formed from silicon, for example, and be positioned over the substrate 51 and under the layer of piezoelectric material 53.

The resonator 50 can generate an acoustic or mechanical wave when an alternating electric potential input signal is applied across the first electrodes 54A-54C and the second electrodes 55A-55C. The electrodes 54A-54C and 55A-55C of the resonator 50 are not positioned on two different, opposing surfaces of the piezoelectric material 53, as in the SMR 30 shown in FIG. 3 and the FBAR 40 shown in FIG. 5. Instead, both the first electrodes 54A-54C and the second electrodes 55A-55C are formed on the top surface of the piezoelectric material 53, which is similar to the SAW resonator 20 shown in FIG. 2. However, the resonator 50 is not designed to excite an acoustic or mechanical wave along the top surface of the resonator 50 like the SAW resonator 20. Instead, the crystal structure c-axis orientation of the piezoelectric material 53 is oriented to excite a bulk acoustic or mechanical wave in the “Z” direction. That is, the c-axis orientation of the piezoelectric material 53 is oriented in the “Z” direction, perpendicular to the top surface of the piezoelectric material 53. Thus, the resonator 50 is referenced as a laterally-excited bulk acoustic wave resonator.

The electrodes 54A-54C and 55A-55C can be embodied as layers of highly conductive material, such as a metal or metal alloy, including copper, silver, gold, molybdenum, tungsten, titanium, platinum, or aluminum, alloys thereof, and other conductive layers. The electrodes 54A-54C and 55A-55C are formed to have a width “W,” with a pitch “P” separating them. The width “W” is smaller than the pitch “P” in the resonator 50. For example, the width “W” can be about 100 nm and the pitch “P” can be between 1-5 μm, although other dimensions can be relied upon.

The layer of piezoelectric material 53 can be embodied as a layer of PZT, BST, BaTiO3, AlScN, AlN, ZnO, or another piezoelectric material. In one preferred embodiment, the layer of piezoelectric material 53 is a layer of AlN, although other piezoelectric materials can be relied upon. In some cases, the layer of piezoelectric material 13 can include one or more layers of piezoelectric material, including two or more different types of piezoelectric material (e.g., a stack of two or more of layers of AlN, PZT, BST, BaTiO3, and AlScN), each of which can be formed using ALD processing techniques according to the embodiments. The encapsulation layer 56 can be embodied as a thin film of material to protect the resonator 50. The encapsulation layer 56 can be a layer of Al₂O₃ for example, another oxide material, or another suitable material to protect the resonator 50.

The operating characteristics of the resonator 50, including the frequency response, the accuracy of the frequency response, and the quality factor are determined in part by the thickness, conformity, and uniformity of the layer of piezoelectric material 53. According to one aspect of the embodiments, the layer of piezoelectric material 53 can be embodied as a layer of AlN deposited by ALD. Forming the layer of AlN using ALD rather than sol-gel wet-chemical techniques, sputtering, pulsed laser deposition, or other techniques can result in thinner, more uniform, and more conformal layers of piezoelectric material.

The layer of piezoelectric material 53 can be formed as a thinner layer of piezoelectric material than in conventional resonators, such as when sputtering is used. In one example, the layer of piezoelectric material 53 can be formed as an AlN layer of 100 nm in thickness or less by ALD. The layer of piezoelectric material 53 can be formed to be a thinner layer of AlN, however, such as a layer of less than 90 nm, 80 nm, 70 nm, 60 nm, 50 nm, 40 nm, 30 nm, or 20 nm in thickness in some cases using ALD. The layer of piezoelectric material 53 is not limited to a layer of AlN, as other thin films of piezoelectric materials can be formed using ALD.

The specific thickness of the layer of piezoelectric material 53 can be highly controlled or tailored in the resonator 50, sometimes to within less than 10 nm of a target thickness, to within less than 5 nm of a target thickness, or even closer to a target thickness by using ALD. The layer of piezoelectric material 53 can be formed as thin as possible using a minimal number of ALD cycles in some embodiments.

The electrodes 54A-54C and 55A-55C can also be formed using ALD. As one example, the electrodes 54A-54C and 55A-55C can be formed as thin copper layers using ALD, but other highly conductive layers can be formed using ALD. If ALD is used to form the electrodes 54A-54C and 55A-55C, the type of conductive material used can be determined in part based on the ALD process available for the material. One factor in the material selection for the electrodes 54A-54C and 55A-55C is the desired thickness of the electrodes 54A-54C and 55A-55C, which is also a factor in the response characteristics of the resonator 50. For example, if very thin and conductive electrodes 54A-54C and 55A-55C are desired, then ALD processing can be selected to deposit copper. In other cases, the electrodes 54A-54C and 55A-55C can be formed by a sputtering process, PVD, or related techniques.

The encapsulation layer 56 can also be formed using ALD according to one aspect of the embodiments. The encapsulation layer 56 can be formed as a uniform and conformal thin film. In one example, the encapsulation layer 56 can be formed as a layer of Al₂O₃ that is 100 nm or thinner, using ALD. The encapsulation layer 56 can also be formed to be a thinner layer of Al₂O₃, such as a layer of less than 10 nm, 5 nm, or thinner in some cases using ALD. The encapsulation layer 56 is not limited to a layer of Al₂O₃, as other thin films of protective materials can be formed using ALD.

The isolation cavity 57 is a space or cavity formed under the layer of piezoelectric material 53. The isolation cavity 57 can vary in size and proportions as compared to that shown in FIG. 8. In some cases, the isolation cavity 57 can be wider than that shown in FIG. 8, and the isolation cavity 57 can be larger (i.e., in a top-down view of length and width dimensions) than the layer of piezoelectric material 53. The isolation cavity 57 can be formed by etching or other material-removal process steps. In some cases, the isolation cavity 57 can be formed with one or more supporting pillars, similar to the supporting pillars 48 shown in FIG. 5.

The overall thickness of the resonator 50 can be significantly reduced by using ALD to form the layer of piezoelectric material 53 as compared to sputtering. The overall thickness can be further reduced by using ALD to form electrodes 54A-54C and 55A-55C and the encapsulation layer 56. The uniformity and conformity of the layer of piezoelectric material 53, the electrodes 54A-54C and 55A-55C, and the encapsulation layer 56 can also be improved by using ALD.

FIG. 9 is a cross-sectional view of another example laterally-excited bulk acoustic wave resonator 60 (“resonator 60”) according to various embodiments described herein. The illustration of the resonator 60 is representative in FIG. 9. The positions, shapes, dimensions, and relative sizes of the layers and features of the resonator 60 are not necessarily drawn to scale in FIG. 9. Example dimensions of the resonator 60 are provided below, but the dimensions are not specifically limited. The layers and other features shown in FIG. 9 are also not exhaustive, and the resonator 60 can include other layers, features, and elements that are not separately illustrated. Additionally, the resonator 60 can be formed as part of a larger integrated structure or circuit in combination with other devices and circuit elements. Such a larger integrated structure may include several resonators similar to the resonator 60, among other integrated components.

The resonator 60 includes a substrate 61, a layer of piezoelectric material 63 over the substrate 61, first electrodes 64A-64C interdigitated with second electrodes 65A-65C, an encapsulation layer 66, an isolation cavity 67, and a floating metal plate 68. The interdigitated electrodes 64A-64C and 65A-65C are similar to the interdigitated electrodes 24 and 25 shown in FIG. 2, although a cross section of the electrodes 64A-64C and 65A-65C is shown in FIG. 9. A limited number of the electrodes 64A-64C and 65A-65C are shown in FIG. 9, but it should be appreciated that a larger number of electrodes can be relied upon in practice. The electrodes 64A-64C and 65A-65C are in contact with a top surface of the piezoelectric material 63. The floating metal plate 68 is in contact with the bottom surface of the piezoelectric material 63.

The substrate 61 can be similar to the substrate 11 shown in FIG. 1 and can be embodied as a silicon, silicon carbide, lithium niobate, sapphire, glass, ceramic, or another suitable type of substrate for the application. Although not shown in FIG. 9, the resonator 60 can also include a supporting layer similar to the supporting layer 42 in FIG. 5 in some cases. Such a layer of supporting material can be formed from silicon, for example, and be positioned over the substrate 61 and under the floating metal plate 68.

The resonator 60 can generate an acoustic or mechanical wave when an alternating electric potential input signal is applied across the first electrodes 64A-64C and the second electrodes 65A-65C. The electric potential is not applied to the floating metal plate 68. The electrodes 64A-64C and 65A-65C of the resonator 50 are not positioned on two different, opposing surfaces of the piezoelectric material 63, as in the SMR 30 shown in FIG. 3 and the FBAR 40 shown in FIG. 5. Instead, both the first electrodes 64A-64C and the second electrodes 65A-65C are formed on the top surface of the piezoelectric material 63, which is similar to the SAW resonator 20 shown in FIG. 2, and the floating metal plate 68 is in contact with the bottom surface of the piezoelectric material 63. The crystal structure c-axis orientation of the piezoelectric material 53 is oriented to excite a bulk acoustic or mechanical wave in the “X” direction, which is into the page in FIG. 9. That is, the c-axis orientation of the piezoelectric material 53 is oriented in the “X” direction, parallel to the top surface of the piezoelectric material 63 and into the page in FIG. 9.

The electrodes 64A-64C and 65A-65C and the floating metal plate 68 can be embodied as layers of highly conductive material, such as a metal or metal alloy, including copper, silver, gold, molybdenum, tungsten, titanium, platinum, or aluminum, alloys thereof, and other conductive layers. The electrodes 64A-64C and 65A-65C are formed to have a width “W,” with a pitch “P” separating them. The width “W” is larger than the pitch “P” in the resonator 60. For example, the width “W” can be about 50-300 μm nm and the pitch “P” can be between 1-20 μm, although other dimensions can be relied upon.

The layer of piezoelectric material 63 can be embodied as a layer of PZT, BST, BaTiO3, AlScN, AlN, ZnO, or another piezoelectric material. In one preferred embodiment, the layer of piezoelectric material 63 is a layer of AlN, although other piezoelectric materials can be relied upon. In some cases, the layer of piezoelectric material 63 can include one or more layers of piezoelectric material, including two or more different types of piezoelectric material (e.g., a stack of two or more of layers of AlN, PZT, BST, BaTiO3, and AlScN), each of which can be formed using ALD processing techniques according to the embodiments. The encapsulation layer 66 can be embodied as a thin film of material to protect the resonator 60. The encapsulation layer 66 can be a layer of Al₂O₃ for example, another oxide material, or another suitable material to protect the resonator 60.

The operating characteristics of the resonator 60, including the frequency response, the accuracy of the frequency response, and the quality factor are determined in part by the thickness, conformity, and uniformity of the layer of piezoelectric material 63. According to one aspect of the embodiments, the layer of piezoelectric material 63 can be embodied as a layer of AlN deposited by ALD. Forming the layer of AlN using ALD rather than sol-gel wet-chemical techniques, sputtering, pulsed laser deposition, or other techniques can result in thinner, more uniform, and more conformal layers of piezoelectric material.

The layer of piezoelectric material 63 can be formed as a thinner layer of piezoelectric material than in conventional resonators, such as when sputtering is used. In one example, the layer of piezoelectric material 63 can be formed as an AlN layer of 100 nm in thickness or less by ALD. The layer of piezoelectric material 53 can be formed to be a thinner layer of AlN, however, such as a layer of less than 90 nm, 80 nm, 70 nm, 60 nm, 50 nm, 40 nm, 30 nm, or 20 nm in thickness in some cases using ALD. The layer of piezoelectric material 63 is not limited to a layer of AlN, as other thin films of piezoelectric materials can be formed using ALD.

The specific thickness of the layer of piezoelectric material 63 can be highly controlled or tailored in the resonator 60, sometimes to within less than 10 nm of a target thickness, to within less than 5 nm of a target thickness, or even closer to a target thickness by using ALD. The layer of piezoelectric material 63 can be formed as thin as possible using a minimal number of ALD cycles in some embodiments.

The electrodes 64A-64C and 65A-65C and the floating metal plate 68 can also be formed using ALD. As one example, the electrodes 64A-64C and 65A-65C and the floating metal plate 68 can be formed as thin copper layers using ALD, but other highly conductive layers can be formed using ALD. If ALD is used to form the electrodes 64A-64C and 65A-65C and the floating metal plate 68, the type of conductive material used can be determined in part based on the ALD process available for the material. One factor in the material selection for the electrodes 64A-64C and 65A-65C and the floating metal plate 68 is the desired thickness of the electrodes 64A-64C and 65A-65C and the floating metal plate 68, which is also a factor in the response characteristics of the resonator 60. In other cases, the electrodes 64A-64C and 65A-65C and the floating metal plate 68 can be formed by a sputtering process, PVD, or related techniques.

The encapsulation layer 66 can also be formed using ALD according to one aspect of the embodiments. The encapsulation layer 66 can be formed as a uniform and conformal thin film. In one example, the encapsulation layer 66 can be formed as a layer of Al₂O₃ that is 100 nm or thinner, using ALD. The encapsulation layer 66 can also be formed to be a thinner layer of Al₂O₃, such as a layer of less than 10 nm, 5 nm, or thinner in some cases using ALD. The encapsulation layer 66 is not limited to a layer of Al₂O₃, as other thin films of protective materials can be formed using ALD.

The isolation cavity 67 is a space or cavity formed under the layer of piezoelectric material 63. The isolation cavity 67 can vary in size and proportions as compared to that shown in FIG. 9. In some cases, the isolation cavity 67 can be wider than that shown in FIG. 9, and the isolation cavity 67 can be larger (i.e., in a top-down view of length and width dimensions) than the layer of piezoelectric material 63. The isolation cavity 67 can be formed by etching or other material-removal process steps. In some cases, the isolation cavity 67 can be formed with one or more supporting pillars, similar to the supporting pillars 48 shown in FIG. 5.

The overall thickness of the resonator 60 can be significantly reduced by using ALD to form the layer of piezoelectric material 63 as compared to sputtering. The overall thickness can be further reduced by using ALD to form electrodes 64A-64C and 65A-65C and the encapsulation layer 66. The uniformity and conformity of the layer of piezoelectric material 63, the electrodes 64A-64C and 65A-65C, and the encapsulation layer 66 can also be improved by using ALD.

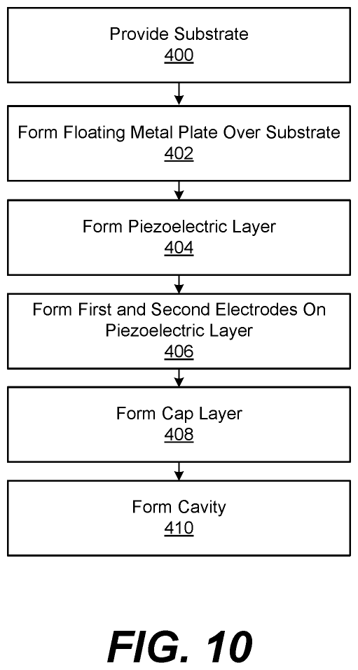

FIG. 10 illustrates an example method of manufacture of the resonator structures 50 and 60 shown in FIGS. 8 and 9 according to various embodiments described herein. Although the method is described in connection with the resonator structures 50 and 60 shown in FIGS. 8 and 9, the method can also be relied upon to manufacture resonator structures similar to those shown. Additionally, although the method illustrates a specific order of steps in FIG. 10, the order of the steps can differ from that which is depicted. For example, two or more steps shown in succession can be performed, at least in part, at the same time. In some cases, one or more of the steps can be skipped or omitted. In other cases, additional steps not shown in FIG. 10 can be relied upon, such as steps among or after the steps shown in FIG. 10.

At step 400, the process includes providing a substrate. Referring to the examples shown in FIGS. 8 and 9, the substrates 51 and 61 are illustrated as example substrates that can be provided at step 400. The substrate can be embodied as a silicon, silicon carbide, lithium niobate, sapphire, glass, ceramic, or another suitable type of substrate for the application. The substrate can be manufactured, sourced from a vendor, or formed or provided in any other suitable way at step 400.

At step 402, the process includes forming the floating metal plate 68 over the substrate. As one example, the floating metal plate 68 can be embodied as a layer of highly conductive material, such as a metal or metal alloy, including copper, silver, gold, molybdenum, tungsten, titanium, platinum, or aluminum, alloys thereof, and other conductive layers. The floating metal plate 68 can be formed using ALD. As one example, the floating metal plate 68 can be formed as a thin copper layer using ALD, but other highly conductive layers can be formed using ALD. In other cases, the floating metal plate 68 can be formed by a sputtering process, PVD, or related techniques. It is also noted that step 402 can be omitted in some cases, such as when forming the resonator 50 in FIG. 8.

At step 404, the process includes depositing a layer of piezoelectric material by ALD processing steps. For example, the layer of piezoelectric material 53 can be deposited on or over the substrate 51 as shown in FIG. 8. In another example, the layer of piezoelectric material 63 can be deposited on or over the floating metal plate 68 as shown in FIG. 9. The ALD process can be started with an initiation for the deposit of piezoelectric material, such as AlN. In a reaction chamber for ALD processing steps, the initiation can include annealing, etching, or exposing surfaces to one or more gases, or other steps to remove contaminants or otherwise prepare surfaces for the deposit of materials using ALD. The crystal orientation of the layer of piezoelectric material can also be directed at step 404. For example, the initiation can be tailored to form the layer of piezoelectric material having a crystal structure c-axis orientation for acoustic or mechanical waves in the “Z” direction shown in FIG. 8 or in the “Y” direction shown in FIG. 9. The layer of piezoelectric material can also be formed to have another crystal structure c-axis orientation in some cases. After initiation, the ALD process at step 404 can proceed with the exposure using precursor chemicals or reactants, in a repeating sequence, as described herein.

The thickness of the layer of piezoelectric material formed at step 404 can be determined by the number of ALD cycles used, and the number of cycles can be tailored to grow the layer of piezoelectric material in a uniform and conformal way, with very high precision. In some cases, step 404 can also include trimming the layer of piezoelectric material formed, to further improve the uniformity of the layer, tailor the thickness of the layer, or otherwise modify the layer of piezoelectric material. Although trimming can be a relatively costly and time-consuming processing, any trimming performed at step 404 can be relatively minor as compared to if sputtering were used.

At step 406, the process includes forming first and second electrodes on the layer of piezoelectric material. For example, the first electrodes 54A-54C and second electrodes 55A-55C can be formed on the layer of piezoelectric material 53, as shown in FIG. 8. As another example, the first electrodes 64A-64C and second electrodes 65A-65C can be formed on the layer of piezoelectric material 63, as shown in FIG. 9. The first and second electrodes can be formed as a thin layer or film of highly conducting material using ALD. The first and second electrodes can be formed at a thickness of 300 nm, 200 nm, or 100 nm or less using ALD. The first and second electrodes can be formed to be a thinner, however, such as a layer of less than 90 nm, 80 nm, 70 nm, 60 nm, 50 nm, 40 nm, 30 nm, or 20 nm in thickness in some cases using ALD.

At step 408, the process includes forming an encapsulation layer over the first and second electrodes. As examples, the encapsulation layer 56 shown in FIG. 8 or the encapsulation layer 66 shown in FIG. 9 can be formed. The encapsulation layer can be formed as a uniform and conformal thin film of Al₂O₃ that is 100 nm or thinner, by ALD processing steps. The encapsulation layer 46 can also be formed to be a thinner layer of Al₂O₃, such as a layer of less than 10 nm, 5 nm, or thinner in some cases using ALD. The encapsulation layer 46 is not limited to a layer of Al₂O₃, as other thin films of protective materials can be formed using ALD.

At step 410, the process includes forming an isolation cavity, such as one of the isolation cavities 57 or 67 shown in FIG. 8 or 9. The isolation cavity can be formed to any suitable size for the purpose of isolating the acoustic waves. In some cases, the isolation cavity can be wider than those shown in FIGS. 8 and 9, and the isolation cavity can be larger (i.e., in a top-down view of length and width dimensions) than the layer of piezoelectric material above it. The isolation cavity can be formed by etching or other material-removal process steps. In some cases, the isolation cavity can be formed with one or more supporting pillars to provide additional support, as described herein.

In some cases, the process shown in FIG. 10 can include additional steps, such as forming one or more temperature compensation layers. For example, the process can include forming a temperature compensation layer, such as a layer of SiO2 or other material for temperature compensation, between steps 404 and 406. In that case, a layer of SiO2 can be formed between the first and second electrodes and the piezoelectric material using ALD. Due to the use of ALD processing steps, the temperature compensation layer or layers can be more uniform, more conformal, and thinner than they would be if formed using other deposition techniques. As some examples, the layer of SiO2 can be formed to be a layer of less than 90 nm, 80 nm, 70 nm, 60 nm, 50 nm, 40 nm, 30 nm, or 20 nm in thickness.

In other cases, the process can include forming a supporting layer over the substrate, after step 400 and before step 402. The supporting layer can be embodied as a layer of silicon, although other supporting layers can be used. The supporting layer can be deposited using a suitable deposition technique, such as PVD, CVD, or a related technique. The supporting layer can be formed to any suitable thickness, and it is not necessary that the supporting layer be formed as a thin film.

Additionally, the process can include forming an acoustic mirror over the substrate, after step 400 and before step 402. The acoustic mirror can be formed as alternating layers of material having high and low acoustic impedance or refractive indexes, such as a Bragg reflector. The acoustic mirror can provide acoustic isolation between the substrate and the resonator formed by the piezoelectric material that is later formed in step 404.

The features, structures, or characteristics described above may be combined in one or more embodiments in any suitable manner, and the features discussed in the various embodiments can be interchangeable among the embodiments. In the foregoing description, certain details are provided to fully present the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although relative terms such as “on,” “below,” “upper,” “lower,” “top,” “bottom,” “right,” and “left” may be used to describe the relative spatial relationships of certain structural features, these terms are used for convenience only, as a direction in the examples. It should be understood that if the device is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them. The “thickness” of the layers described herein can be measured from the top to the bottom of the page (i.e., in the “Z” direction) in the cross-sectional views.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc., are used only as labels, rather than a limitation for a number of the objects.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A method of manufacturing an acoustic resonator, comprising:
providing a substrate;
depositing a layer of piezoelectric material over the substrate by atomic layer deposition; and
forming an electrode in contact with the layer of piezoelectric material.

2. The method of claim 1, wherein:
the electrode comprises a first electrode; and
the method further comprises forming a second electrode in contact with the piezoelectric material.

3. The method of claim 2, wherein the first electrode and the second electrode are formed by sputtering metal.

4. The method of claim 2, wherein:
the first electrode is formed by atomic layer deposition of metal; and
the second electrode is formed by sputtering metal.

5. The method of claim 2, wherein the first electrode and the second electrode are formed by atomic layer deposition of metal.

6. The method of claim 2, wherein, in a stack of material layers of the acoustic resonator, the first electrode and the second electrode are both formed at least in part over the layer of piezoelectric material.

7. The method of claim 2, wherein, in a stack of material layers of the acoustic resonator:
the first electrode is formed at least in part under the layer of piezoelectric material; and
the second electrode is formed at least in part over the layer of piezoelectric material.

8. The method of claim 1, further comprising forming an acoustic reflector over the substrate, between the substrate and the layer of piezoelectric material.

9. The method of claim 8, wherein the reflector comprises a plurality of layers of material, the plurality of layers comprising alternating layers of material having varying refractive indexes.

10. The method of claim 1, further comprising forming a supporting layer over the substrate, between the substrate and the layer of piezoelectric material.

11. The method of claim 10, further comprising forming an air cavity in the substrate in a region below the piezoelectric material.

12. The method of claim 11, wherein the cavity comprises a plurality of supporting pillars.

13. The method of claim 1, further comprising, after depositing the layer of piezoelectric material by atomic layer deposition, trimming the layer of piezoelectric material.

14. The method of claim 1, wherein the piezoelectric material comprises aluminum nitride.

15. The method of claim 1, further comprising forming an encapsulation layer over the electrode by atomic layer deposition.

16. An acoustic resonator, comprising:
a substrate;
a layer of piezoelectric material deposited over the substrate by atomic layer deposition; and
an electrode in contact with the layer of piezoelectric material.

17. The acoustic resonator of claim 16, wherein the layer of piezoelectric material comprises a layer of aluminum nitride that is equal to or less than 100 nm in thickness.

18. The acoustic resonator of claim 16, further comprising:
a second electrode in contact with the piezoelectric material, wherein:
at least one of the electrode or the second electrode is formed by atomic layer deposition of metal.

19. The acoustic resonator of claim 16, further comprising an acoustic reflector over the substrate, between the substrate and the layer of piezoelectric material.

20. The acoustic resonator of claim 16, further comprising a supporting layer over the substrate, between the substrate and the layer of piezoelectric material.
